(19) United States
(12) Patent Application Publication
(10) Pub. No.: US 2007/0052457 A1
(43) Pub. Date: Mar. 8, 2007

(54) FREQUENCY-DIVIDER CIRCUIT ARRANGEMENT

(75) Inventors: Roland Thewes, Groebenzell (DE); Christian Pacha, Muenchen (DE); Ralf Brederlow, Poing (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(73) Assignee: INFINEON TECHNOLOGIES AG, Muenchen (DE)

(21) Appl. No.: 11/470,470

(22) Filed: Sep. 6, 2006

(30) Foreign Application Priority Data
Sep. 6, 2005 (DE) 102005042309.4-31

(51) Int. Cl. H03K 23/00

(52) U.S. Cl. 327/115

(57) ABSTRACT

A frequency-divider circuit arrangement having a power supply, a first clock signal, a second clock signal, a first switch unit, a first capacitance which is connected downstream from the first switch unit is disclosed. A second switch unit is connected downstream from the first capacitance and is controlled by the second clock signal, a second capacitance is connected downstream from the second switch unit and is connected in parallel to the first capacitance, a clock-signal control unit, a capacitance discharge device and a capacitance discharge device control unit.

### CROSS-REFERENCE TO RELATED APPLICATIONS

This Utility Patent Application claims priority to German Patent Application No. DE 10 2005 042 309.4-31 filed on Sep. 6, 2005, which is incorporated herein by reference.

### FIELD OF THE INVENTION

The invention relates to a frequency-divider circuit arrangement.

### BACKGROUND

In digital circuit technology, it is often necessary to produce an electrical clock signal which is at a lower frequency than a reference clock signal. This can be achieved by a frequency-divider circuit. Typically, a frequency-divider circuit such as this should generate power losses which are as low as possible.

### SUMMARY

The invention provides for a frequency-divider circuit arrangement having a power supply, a first clock signal, a second clock signal, and a first switch unit. A first capacitance is connected downstream from the first switch unit, and a second switch unit is connected downstream from the first capacitance and is controlled by the second clock signal. A second capacitance which is connected downstream from the second switch unit and is connected in parallel to the first capacitance, a clock-signal control unit, a capacitance discharge device and a capacitance discharge device control unit.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a frequency-divider circuit arrangement having a division ratio of 1:2^{Z}.

FIG. 2 illustrates one possible clock scheme diagram for two clock signals and the associated complementary signals.

FIG. 3 illustrates a circuit arrangement in order to explain the principle on which the invention is based.

FIG. 4 illustrates a diagram of a voltage waveform of the circuit arrangement illustrated in FIG. 3.

FIG. 5 illustrates a frequency-divider circuit arrangement according to a first embodiment of the invention.

FIG. 6 illustrates a diagram of a voltage waveform for the frequency-divider circuit arrangement according to the first embodiment of the invention.

FIG. 7 illustrates a frequency-divider circuit arrangement according to a second embodiment of the invention.

FIG. 8 illustrates a diagram of a voltage waveform for the frequency-divider circuit arrangement according to the second embodiment of the invention.

FIG. 9 illustrates a diagram of a cycle parameter.

FIG. 10 illustrates a diagram of the magnitude of a last voltage step on a capacitance.

FIG. 11 illustrates an enlarged detail from the diagram illustrated in FIG. 10.

FIG. 12 illustrates the diagram in FIG. 10 with logarithmic scaling.

FIG. 13 illustrates a frequency-divider circuit arrangement according to a third embodiment of the invention.

FIG. 14 illustrates a frequency-divider circuit arrangement according to a fourth embodiment of the invention.

FIG. 15 illustrates a diagram of a second voltage, which has been normalized with respect to a first reference voltage, for a balanced threshold-value voltage, according to the third embodiment and according to the fourth embodiment of the invention.

FIG. 16 illustrates a diagram of a second voltage, which has been normalized with respect to a first reference voltage, for an unbalanced threshold-value voltage, according to the third embodiment and according to the fourth embodiment of the invention.

FIG. 17 illustrates a diagram for the cycle parameter with a balanced reference and threshold-value voltage according to the third embodiment and according to the fourth embodiment of the invention.

FIG. 18 illustrates a diagram for the magnitude of a last voltage step on a capacitance with balanced reference and threshold-value voltages according to the third embodiment and according to the fourth embodiment of the invention.

FIG. 19 illustrates an enlarged detail of the diagram illustrated in FIG. 18.

FIG. 20 illustrates the diagram in FIG. 18 with logarithmic scaling, according to the third embodiment and according to the fourth embodiment of the invention.

FIG. 21a illustrates a circuitry implementation of a part of the frequency-divider circuit arrangement according to the first embodiment of the invention.

FIG. 21b illustrates a circuitry implementation of a part of the frequency-divider circuit arrangement by means of transistors, according to the first embodiment of the invention.

FIG. 22 illustrates a circuitry implementation of the frequency-divider circuit arrangement according to the second embodiment of the invention.

FIG. 23 illustrates a circuitry implementation of the frequency-divider circuit arrangement according to the fourth embodiment of the invention.

FIG. 24 illustrates circuit arrangements for virtually loss-free production of reference, threshold-value and bias voltages.

FIG. 24a illustrates a circuit arrangement which can be used in the frequency-divider circuit arrangements illustrated in FIGS. 21a, 21b and 22.

FIG. 24b illustrates a voltage-divider chain composed of transistors, which can be used in the frequency-divider circuit arrangements illustrated in FIGS. 21a, 21b and 22.

FIG. 24c illustrates a combination of the circuit arrangements illustrated in FIGS. 24a and 24b, and

FIG. 24d illustrates a circuit arrangement which can be used in the frequency-divider circuit arrangement illustrated in FIG. 23.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

A frequency-divider circuit is frequently used in digital circuit technology in order to derive a signal at a low clock frequency from a signal at a high clock frequency. A circuit such as this is implemented, by way of example, in a non-contacting RF-ID tag circuit.

An RF-ID tag circuit is normally operated at a lower frequency than the frequency of a signal which is used for wire-free signal transmission purposes. The energy which is required for operation of an RF-ID tag circuit is normally taken from a radio-frequency, electromagnetically transmitted signal which is received by means of a receiving apparatus in the RF-ID tag circuit, such as an antenna or a coil. The radio-frequency signal is frequently at a frequency in the region of several 100 MHz up to a few GHz, while in contrast the RF-ID tag circuit is normally operated at a considerably lower clock frequency, for example in the order of magnitude of a few 10 MHz, or even less.

In one embodiment, a divider circuit is used in a counter circuit or in a decoder, and is frequently used to produce one or more low-frequency clock signals from a higher-frequency clock signal, also referred to as a master clock, and is thus used as a input stage or input circuit for a downstream circuit.

A high carrier frequency allows the implementation and provision of small antennas in RF-ID tags, thus resulting in a cost advantage. Furthermore, a low clock frequency in an RF-ID tag circuit is worthwhile since the power consumption of the circuit, and thus also the requirement for provision and non-contacted transmission of this power, falls approximately in proportion to the clock frequency of the circuit. This illustrates that it would be desirable to use high carrier frequencies and to derive the clock frequency that is required for operation of the circuit from the carrier frequency by means of a frequency-divider circuit.

When frequency-divider circuits are cascaded, the first stage of a divider circuit contributes the majority of the power consumption of a circuit such as this, because of the high switching activity and temporary parallel currents resulting from this, during a respective switching process from a supply potential VDD to a ground potential GND. In particular, the power consumption of each stage is, to a good approximation, proportional to the frequency of the input signal to the stage, so that, in accordance with the following equation (1), the first stage consumes approximately half of the power of the entire divider circuit, the second stage a quarter, the third an eighth, and so on:

$${f}_{in} > \frac{{f}_{in}}{2} + \frac{{f}_{in}}{4} + \frac{{f}_{in}}{8} + … + \frac{{f}_{in}}{{2}^{z - 1}} + \frac{{f}_{in}}{{2}^{z}} = {f}_{in} * ( 1 - {2}^{z + 1} ) \qquad ( 1 )$$

where fᵢₙ is the frequency of the input signal to the divider circuit, and z is the number of divider stages in the frequency-divider circuit.

According to one embodiment of the invention, a frequency-divider circuit arrangement which results in reduced power losses being produced is provided.

According to one embodiment of the invention, a frequency-divider circuit arrangement is provided, the frequency-divider circuit arrangement having a first switch unit (which can be coupled to a power supply potential and is controlled by a first clock signal), a first capacitance (which is connected downstream from the first switch unit), a second switch unit (which is connected downstream from the first capacitance and is controlled by a second clock signal), a second capacitance (which is connected downstream from the second switch unit and is connected in parallel with the first capacitance), a clock-signal control unit (which applies the first clock signal and the second clock signal to the first switch unit and to the second switch unit, respectively, in such a manner that the following process is carried out repeatedly:

the first switch unit is closed such that the first capacitance is electrically charged,

the first switch unit is opened,

the second switch unit is closed so that charge equalization takes place between the first capacitance and the second capacitance,

the second switch unit is opened),

the frequency-divider circuit arrangement further having a capacitor discharge device for electrically discharging the second capacitance to a predetermined electrical voltage value, and a capacitor discharge device control unit for controlling the capacitor discharge device in such a manner that it is activated when the electrical voltage which is applied to the second capacitance is greater than a predetermined threshold value.

According to one embodiment of the invention, the power consumption of a first stage of a frequency-divider circuit, and thus the power loss, are minimized by means of a simple circuit architecture.

In one embodiment of the invention, the high switching activity in a first stage of a frequency-divider circuit during a switching process from a supply potential VDD to a ground potential GND, and the temporary parallel currents associated with it, are reduced.

The power consumption of the overall frequency-divider circuit is thus reduced.

According to one embodiment of the invention, a method for frequency division is provided, the method including: controlling a first switch unit which can be coupled to a power supply potential, by means of a first clock signal, controlling a second switch unit by means of a second clock signal, in which the second switch unit is connected downstream from a first capacitance and the first capacitance is connected downstream from the first switch unit, applying the first clock signal to the first switch unit and applying the second clock signal to the second switch unit in such a manner that the following process is carried out repeatedly:

the first switch unit is closed such that the first capacitance is electrically charged,

the first switch unit is opened,

the second switch unit is closed so that charge equalization takes place between the first capacitance and a second capacitance which is connected downstream from the second switch unit and is connected in parallel with the first capacitance,

the second switch unit is opened.

The method further includes electrically discharging the second capacitance to a predetermined electrical voltage value when the electrical voltage which is applied to the second capacitance is greater than a predetermined threshold value.

According to a further embodiment of the invention, a frequency-divider circuit arrangement is provided which includes a first switch unit which is controlled by a first clock signal and can be coupled to a power supply potential, a first capacitance, which is connected downstream from the first switch unit, a second switch unit, which is connected downstream from the first capacitance and is controlled by a second clock signal, a second capacitance, which is connected downstream from the second switch unit and is connected in parallel with the first capacitance, and a clock-signal control unit, which applies the first clock signal to the first switch unit and applies the second clock signal to the second switch unit in such a manner that the second capacitance is charged in a stepped manner in that the following process is carried out repeatedly:

the first switch unit is closed such that the first capacitance is electrically charged,

the first switch unit is opened,

the second switch unit is closed so that charge equalization takes place between the first capacitance and the second capacitance,

the second switch unit is opened.

The frequency-divider circuit arrangement also includes a capacitance discharge device which electrically discharges the second capacitance to a predetermined electrical voltage value, and a capacitance discharge device control unit, which controls the capacitance discharge device in such a manner that it is activated when the electrical voltage which is applied to the second capacitance is greater than a predetermined threshold value.

In one embodiment, the second capacitance has a capacitance value which is different to that of the first capacitance.

In another embodiment, the value of the second capacitance is greater than the value of the first capacitance.

According to one embodiment of the invention, the capacitance discharge device includes a switch.

In one embodiment, the capacitance discharge device control unit includes a first comparator unit, which compares the electrical voltage applied to the second capacitance with the predetermined threshold value, and produces a comparison-result signal at its output.

According to one embodiment of the invention, the capacitance discharge device control unit includes a delay element, which is connected between the output of the first comparator unit and the capacitance discharge device, in order to delay the comparison-result signal.

According to one embodiment of the invention, the delay element includes a latch.

In one embodiment, the capacitance discharge device control unit includes a switching element, a first logic element and a second logic element.

According to one embodiment of the invention, the switching element is a flip-flop, which includes a first input, a second input, a first output and a second output, and by way of example is coupled by the first input to the output of the first comparator unit, and is clocked by means of the first clock signal, which is applied to the second input.

The first logic element and the second logic element may be in the form of AND gates, which each comprise a first input, a second input and one output; in which the first input of the first logic element is electrically coupled to the second output of the first switching element, the second clock signal can be applied to the second input of the first logic element, and the output of the first logic element is electrically coupled to the third switch unit, such that the capacitance discharge device can be switched as a function of the output signal from the first logic element; in which the first input of the second logic element is electrically coupled to the first output of the first switching element, the second clock signal can be applied to the second input of the second logic element, and the output of the second logic element is electrically coupled to the second switch unit, such that the second switch unit can be switched as a function of the output signal from the second logic element.

In one embodiment, the capacitance discharge device control unit includes an inverter circuit, a first logic element and a second logic element.

According to one embodiment of the invention, the first switch unit includes a first switch unit element and a second switch unit element, in which a first power supply potential can be applied to a first connection of the first switch unit element, in which a second connection of the first switch unit element is coupled to the first capacitance, in which a second power supply potential can be applied to a first connection of the second switch unit element, in which a second connection of the second switch unit element is coupled to the first capacitance; in which the first logic element and the second logic element are AND gates which each comprise a first input, a second input and one output; in which the first input of the first logic element is electrically coupled to the output of the comparator unit, the first clock signal can be applied to the second input of the first logic element, and the output of the first logic element is electrically coupled to the second switch unit element, such that the second switch unit element can be switched as a function of the output signal from the first logic element; in which the first input of the second logic element is electrically coupled to the output of the inverter circuit, the first clock signal can be applied to the second input of the second logic element, and the output of the second logic element is electrically coupled to the first switch unit element, such that the first switch unit element can be switched as a function of the output signal from the second logic element.

According to one embodiment of the invention, the frequency-divider circuit arrangement includes a fourth switch unit, at whose first connection a first comparison potential can be applied, and whose second connection is coupled to a first input of the comparator unit, whose control connection is coupled to the output of the inverter circuit; includes a fifth switch unit, to whose first connection a second comparison potential can be applied, and whose second connection is coupled to the first input of the comparator unit, whose control connection is coupled to the output of the comparator unit; in which the second input of the comparator unit is coupled to the second capacitance.

The first switch unit may include a first switch unit element and a second switch unit element, in which a first power supply potential can be applied to a first connection of the first switch unit element, in which a second connection of the first switch unit element is coupled to the first capacitance; in which a second power supply potential can be applied to a first connection of the second switch unit element, in which a second connection of the second switch unit element is coupled to the first capacitance; in which the first logic element and the second logic element are in the form of AND gates which each comprise a first input, a second input and one output; in which the first input of the first logic element is electrically coupled to the second output of the switching element, the first clock signal can be applied to the second input of the first logic element, and the output of the first logic element can be coupled to the second switch unit element, such that the second switch unit element can be switched as a function of the output signal from the first logic element; in which the first input of the second logic element is electrically coupled to the first output of the switching element, the first clock signal can be applied to the second input of the second logic element, and the output of the second logic element is electrically coupled to the first switch unit element, such that the first switch unit element can be switched as a function of the output signal from the second logic element.

According to one embodiment of the invention, a first comparison potential can be applied to a first input of the first comparator unit, a second input of the first comparator unit is coupled to the second capacitance, and the output of the first comparator unit is coupled to a first input of the switching element.

By way of example, the frequency-divider circuit arrangement includes a second comparator unit, whose first input is coupled to the second capacitance, to whose second input a second comparison potential can be applied, and whose output is coupled to a second input of the switching element.

According to one embodiment of the invention, a first capacitance is clearly charged by means of a power supply potential, for which purpose a first switch unit electrically connects the first capacitance to a power supply potential. After the process of charging the first capacitance, the electrical contact between the first capacitance and the power supply potential is disconnected. The first capacitance and a second capacitance are then electrically coupled to one another by means of a second switch unit, and this results in charge equalization between the first capacitance and the second capacitance. Depending on the values of the capacitances, the charge is distributed proportionally between the first capacitance and the second capacitance, as a result of which a potential is produced across the second capacitance. After charge equalization, the electrical connection between the first capacitance and the second capacitance is disconnected. After the connection of the capacitances, this therefore results in the same voltage or the same potential across both capacitances.

Where expedient, identical reference symbols are provided for the same or similar elements in the figures.

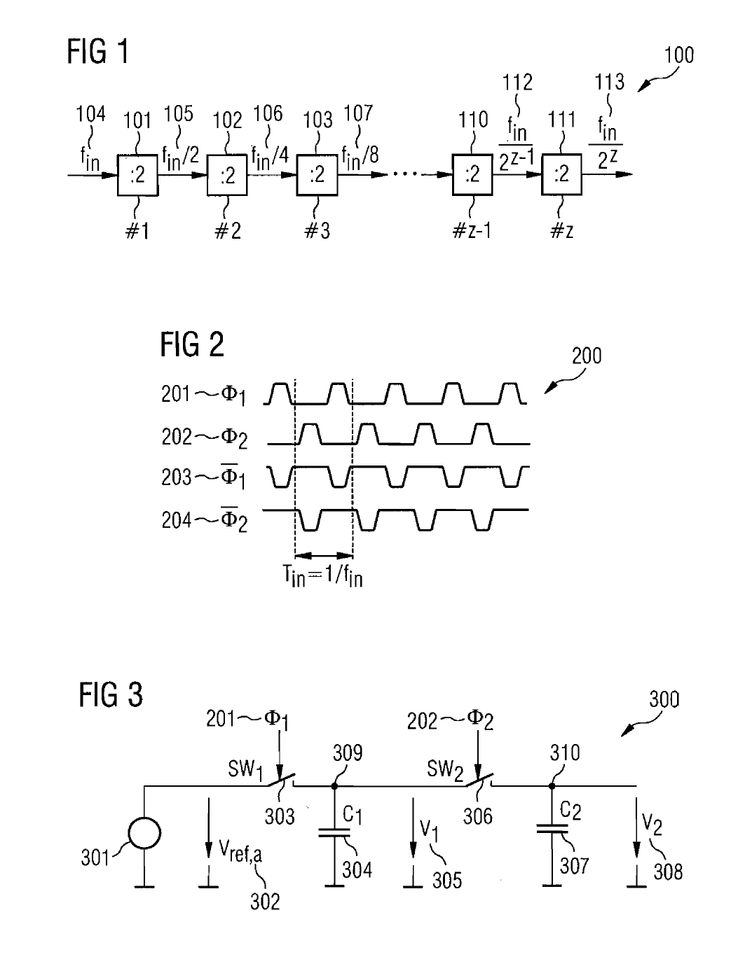

One embodiment of a frequency-divider circuit arrangement will be described in the following text with reference to FIG. 1.

The frequency-divider circuit arrangement illustrated in FIG. 1 and having an overall division ratio 1:2^{z} includes z series-connected: 2-frequency-divider circuits 101, 102, 103, 110 and 111, in which the output of one frequency-divider circuit is in each case coupled to the input of the frequency-divider circuit coupled immediately downstream from it. The frequency-divider circuits 101, 102, 103, 110 and 111 are each designed in such a manner that they halve the frequency of the input signal supplied to each of them, and produce an output signal whose frequency is half the frequency of the input signal. In detail, this means that an input signal at a frequency fᵢₙ 104 is applied to the input of a first frequency-divider circuit 101. The first frequency-divider circuit 101 halves the frequency of the input signal 104, and produces a signal 105, at the frequency fᵢₙ/2, which is half the frequency of the input signal 104. The signal 105 is then applied to the input of the frequency-divider circuit 102. The second frequency-divider circuit 102 halves the frequency of the signal 105, and produces a signal 106 at a frequency fᵢₙ/4 which is half the frequency of the signal 105. The signal 106 is then applied to the input of the third frequency-divider circuit 103. The third frequency-divider circuit 103 halves the frequency of the signal 106, and produces a signal 107 at a frequency fᵢₙ/8 which is half the frequency of the signal 106. This process continues, for example, as far as the frequency-divider circuits 110 and 111, in which, in a penultimate step, the frequency-divider circuit 110 reduces the frequency of the signal applied to the input of the frequency-divider circuit 110 to a value fᵢₙ/2^{z-1} 112 of the frequency of the input signal 104, as a function of the number z of frequency-divider circuits. The frequency of the signal 112 which is applied to the input of the frequency-divider circuit 111 is reduced by means of this, in a final step, to a value fᵢₙ/2^{z} of the frequency of the input signal 104 as a function of the number z of frequency-divider circuits.

A clock-scheme diagram 200 will be described in the following text with reference to FIG. 2.

The clock-scheme diagram 200 illustrates the signal waveform of a first clock signal Φ₁ 201 and of a second clock signal Φ₂ 202, as well as the signals Φ̅₁̅ 203 and Φ̅₂̅ 204, which are complementary to the clock signals Φ₁ 201, Φ₂ 202, and are used in specific circuitry implementations. Furthermore, the clock-scheme diagram 200 illustrates the duration of a period Tᵢₙ, which is calculated from the reciprocal of the frequency of the input signal fᵢₙ.

The first clock signal Φ₁ 201 and the second clock signal Φ₂ 202 respectively assume a high state and a low state, in which case, by way of example, a high state means a voltage of 1.5 V, and a low state means a ground potential or 0 V, in which case the first clock signal Φ₁ 201 and the second clock signal Φ₂ must not both be in the same signal state at the same time, that is to say a high state. The high state is thus a non-overlapping clock signal.

A block diagram 300 will be described in the following text with reference to FIG. 3, in which the functional principle on which the embodiments are based will be described with reference to one embodiment of the invention.

The outline circuit diagram includes a first reference voltage source 301, which produces a first reference voltage V_{ref,a} 302, a first switch unit SW₁ 303, a first capacitance C₁ 304, a second switch unit SW₂ 306 and a second capacitance C₂ 307.

The first reference voltage source 301 is coupled by a first connection to the first switch unit SW₁ 303 and by a second connection to a ground potential GND. The first switch unit SW₁ 303 is coupled by a second connection to a first connection of the first capacitance C₁ 304. The first capacitance C₁ 304 is coupled by a second connection to a ground potential GND, and by the first connection to a first connection of the second switch unit SW₂ 306. The second switch unit SW₂ 306 is coupled by a second connection to a first connection of the second capacitance C₂ 307, and the second capacitance C₂ 307 is coupled by a second connection to a ground potential GND.

Furthermore, the series circuit having the first reference voltage source 301 and the first switch unit SW₁ 303 is connected in parallel with the first capacitance C₁ 304. The series circuit having the first capacitance C₁ 304 and the second switch unit SW₂ 306 is connected in parallel with the second capacitance C₂ 307.

Furthermore, a first voltage V₁ 305 can be tapped off between a first node 309 and a ground potential GND, and a second voltage V₂ 308 can be tapped off between a second node 310 and the ground potential.

The first switch unit SW₁ 303 is controlled by means of the first clock signal Φ₁ 201, and the second switch unit SW₂ 306 is controlled by means of the second clock signal Φ₂ 202, with the first switch unit SW₁ 303 being closed when the first clock signal Φ₁ 201 changes from a low state to a high state, and being opened when the first clock signal Φ₁ 201 changes from a high state to a low state.

The circuit arrangement 300 is driven in such a way that, when the signal changes from a low state to a high state of the first clock signal Φ₁ 201, the first switch unit SW₁ 303 is closed, and remains closed until the next signal state change, as a result of which the first reference voltage source 301 and the first capacitance C₁ 304 are electrically coupled to one another, and the first capacitance C₁ 304 is charged to the value of the first reference voltage V_{ref,a} 302, by means of that first reference voltage V_{ref,a} 302, which is produced by the first reference voltage source 301. When the first clock signal Φ₁ 201 changes from a high state to a low state, the first switch unit SW₁ 303 is opened, and remains open until the next signal state change, as a result of which the first reference voltage source 301 is decoupled from the first capacitance C₁ 304. The second clock signal Φ₂ 202 then changes from a low state to a high state, as a result of which the second switch unit SW₂ 306 is closed, and the first capacitance C₁ 304 and the second capacitance C₂ 307 are electrically coupled to one another. Charge equalization or potential equalization then takes place between the first capacitance C₁ 304 and the second capacitance C₂ 307, with the sum of the charges being distributed between the first capacitance C₁ 304 and the second capacitance C₂ 307 in proportion to the values of the capacitances C₁ 304, C₂ 307, in such a manner that the same voltage or the same potential is produced across the first capacitance C₁ 304 and across the second capacitance C₂ 307.

Furthermore, the time period during which the first clock signal Φ₁ 201 and the second clock signal Φ₂ 202 are in a high state is sufficiently long that either the first capacitance C₁ 304 is charged completely by means of the first reference voltage V_{ref,a} 302 which is produced by the first reference voltage source 301, or the second capacitance C₂ 307 and the first capacitance C₁ 304 are at exactly the same potential.

In other words, the first switch unit SW₁ 303 and the second switch unit SW₂ 306 are controlled as a function of the frequency of the input clock signal by means of the clock signals Φ₁ 201, Φ₂ 202, which are non-overlapping signals derived from the input clock signal to the circuit 300 at the frequency fᵢₙ or a period Tᵢₙ, with the first switch unit SW₁ 303 being closed when the first clock signal Φ₁ 201 changes from a low state to a high state, as a result of which the first capacitance C₁ 304 is coupled to the first reference voltage source 301 by means of the first switch unit SW₁ 303, which is controlled by the first clock signal Φ₁ 201, and is charged by means of the first reference voltage V_{ref,a} 302, which is produced by the first reference voltage source 301. In consequence, the first reference voltage V_{ref,a} 302 is always present across the first capacitance C₁ 304 after a charging process following the opening of the first switch unit SW₁ 303 and before the closing of the second switch unit SW₂ 306. After a predetermined time period, during which the first switch unit SW₁ 303 and the second switch unit SW₂ 306 are open, that is to say the first clock signal Φ₁ 201 and the second clock signal Φ₂ 202 are in a low state, the second switch unit SW₂ 306 is closed when the second clock signal Φ₂ 202 changes from a low state to a high state, so that the first capacitance C₁ 304 and the second capacitance C₂ 307 are electrically coupled to one another. In consequence, the sum of the charge is distributed proportionally between the first capacitance C₁ 304 and the second capacitance C₂ 307 on the basis of the capacitance values of the first capacitance C₁ 304 and of the second capacitance C₂ 307, so that the same voltage or the same potential is then produced across the first capacitance C₁ 304 and across the second capacitance C₂ 307.

Furthermore, the second capacitance C₂ 307 should be adequately protected against the first reference voltage V_{ref,a} 302 which is produced by the first reference voltage source 301, that is to say the second capacitance C₂ 307 is not charged by means of the first reference voltage V_{ref,a} 302, thus resulting in the time duration mentioned above, in which the first switch unit SW₁ 303 and the second switch unit SW₂ 306 are open, with this being a precondition which also applies to the other embodiments of the invention in the following text. One precondition for this is that the first switch unit SW₁ 303 and the second switch unit SW₂ 306 have a sufficiently high impedance when in the open state. A further precondition for the correct operation of the circuit is that the first switch unit 303 as well as the second switch unit 306 have a low impedance in the switched-on state, so that the switching times for the first switch unit SW₁ 303 and for the second switch unit SW₂ 306 are short, in order to ensure complete equalization of the potentials between the first capacitance C₁ 304 and the second capacitance C₂ 307.

The time period during which the first switch unit 303 and the second switch unit 306 are open at the same time is, for example, between 10 and 100 ps (picoseconds), with this time period depending essentially on the technology being used. The circuit arrangement 300 described above is designed for opening and closing of the first switch unit 303 and of the second switch unit 306, with the opening and closing processes being repeated periodically. Furthermore, the circuit arrangement 300 is designed such that, over two successive periods, the potential from the previous period applies to the first capacitance C₁ 304 and to the second capacitance C₂ 307, that is to say the first capacitance C₁ 304 and the second capacitance C₂ 307 are charged in steps.

A mathematical derivation of the fundamental principle of operation will be described in the following text, with the reference symbols being omitted, for the sake of clarity.

According to equation (2), a quotient of the two values of the capacitances is defined as follows:

$$η = \frac{{C}_{1}}{{C}_{1} + {C}_{2}} \qquad ( 2 )$$

where C₁ is the value of the first capacitance, C₂ is the value of the second capacitance, and η denotes the quotient. Furthermore, without any restriction to generality, it is assumed that the first capacitance C₁, and the second capacitance C₂ have been charged to 0 V (ground potential GND) before the first activation of the first switch unit.

The first voltage V₁ (this applies to any voltage V₁ after the charging process) across the first capacitance C₁ corresponds, according to the following equation, to the reference voltage V_{ref,a} of the power supply potential after a charging process.

$${V}_{1} ( t = \text{(} n + \frac{1}{2} * {T}_{in} ) = {V}_{ref , a} \qquad ( 3 )$$

The parameter n=0, 1, 2, 3 . . . is a natural number, by means of which the number of periods Tᵢₙ in one cycle are counted, this being the number that the circuit has carried out since an initial state. When n>0:

$$\begin{matrix}{V}_{2} ( t = n * {T}_{in} ) = {V}_{2} ( t = ( n - 1 ) * {T}_{in} ) * \frac{{C}_{2}}{{C}_{1} + {C}_{2}} + {V}_{ref , a} * η \\ = {V}_{2} ( t = ( n - 1 ) * {T}_{in} ) * ( 1 - η ) + {V}_{ref , a} * η\end{matrix} \qquad ( 4 )$$

Subject to the condition that the second capacitance C₂ is in a state of charge other than zero, equation (4) describes the charge equalization process carried out between the first capacitance C₁ and the second capacitance C₂. According to equation (4), the second voltage V₂ at the time t=n*Tᵢₙ can be determined recursively from the second voltage V₂ at the time t=(n−1)*Tᵢₙ. Equation (4) can be converted to equation (5) by a number of conversion operations, showing that the second voltage V₂ at the time t=n*Tᵢₙ can also be determined from the second voltage V₂ at the time t=(n−m)*Tᵢₙ, where m is a natural number which can be chosen as required within the interval 0≦m≦n.

$${V}_{2} ( t = n * {T}_{in} ) = {V}_{2} ( t = ( n - m ) * {T}_{in} ) * {( 1 - η )}^{m} + {V}_{ref , a} * η * {\sum }_{k = 0}^{m - 1} {( 1 - η )}^{k} \qquad ( 5 )$$

After further conversion operations based on the mathematical series development:

$${\sum }_{k = 0}^{m - 1} {q}^{k} = \frac{1 - {q}^{m}}{1 - q}$$

Equation (5) can be written as follows:
V₂(t=n*Tᵢₙ)=
V₂(t=(n−m)*Tᵢₙ)*(1−η)^{m}+V_{ref,a}*[1−(1−η)^{m}] (6)

in which case the term

$$η * {\sum }_{k = 0}^{m - 1} {( 1 - η )}^{k}$$

can be converted in accordance with the series development as described above as follows:

$$\begin{matrix}η * {\sum }_{k = 0}^{m - 1} {( 1 - η )}^{k} = η * \{ \frac{1 - {( 1 - η )}^{k}}{1 - ( 1 - η )} \} {\vert}_{k = 0}^{m - 1} \\ = η * \{ \frac{1 - {( 1 - η )}^{0}}{1 - ( 1 - η )} + \frac{1 - {( 1 - η )}^{m}}{1 - ( 1 - η )} \} \\ = η * \{ \frac{1 - 1}{1 - ( 1 - η )} + \frac{1 - {( 1 - η )}^{m}}{1 - 1 + η} \} \\ = η * \{ 0 + \frac{1 - {( 1 - η )}^{m}}{η} \} \\ = η * \{ \frac{1 - {( 1 - η )}^{m}}{η} \} \\ = \underline{\underline{1 - {( 1 - η )}^{m}}} ;\end{matrix}$$

In particular, for (n=m):
V₂(t=n*Tᵢₙ)=V₂(t=0)*(1−η)ⁿ+V_{ref,a}*[1−(1−η)ⁿ] (7)

and, after further conversion operations, this results in:
V₂(t=n*Tᵢₙ) V_{ref,a}+[V₂(t=0)−V_{ref,a}]*(1−η)ⁿ (8)

The relationships explained above can be used in particular to determine the number of steps N which are required for given values of η and V_{ref,a} in order, starting from an initial value V_{2,start} and using
V_{2,start}=V₂(t=0) (9a)

to reach a final value V_{2,end}, such that the following equation is satisfied:
V₂(t=(N−1)*Tᵢₙ)<V_{2,end}≦V₂(t=N*Tᵢₙ) (9b)

where, for N:

$$N = \{ \begin{matrix}\frac{ln ( 1 - \frac{{V}_{2} , end - {V}_{2} , start}{{V}_{ref , a} - {V}_{2} , start} )}{ln ( 1 - η )} & if an integer \\ int ( \frac{ln ( 1 - \frac{{V}_{2} , end - {V}_{2} , start}{{V}_{ref , a} - {V}_{2} , start}}{ln ( 1 - η )} ) + 1 & else\end{matrix} \qquad ( 10 )$$

in which case the validity of this formula can be derived recursively from the equation (10) as follows:

$$N = \frac{ln ( 1 - \frac{{V}_{2} , end - {V}_{2} , start}{{V}_{ref , a} - {V}_{2} , start}}{ln ( 1 - η )} \hat{=} \frac{ln a}{ln b} ,$$

where, in general:
N*ln b=ln a
ln b^{N}=ln a
b^{N}=a

Furthermore, using the definitions:
V_{2,end}=V₂(t=N*Tᵢₙ)
V_{2,start}=V₂(t=0)

it is possible to illustrate that:

$${( 1 - η )}^{N} = 1 - \frac{{V}_{2} ( t = N * {T}_{i n} ) - {V}_{2} ( t = 0 )}{{V}_{ref , a} - {V}_{2} ( t = 0 )}$$

where, next, the fraction is extended to:

$${( 1 - η )}^{N} = \frac{( {V}_{ref , a} - {V}_{2} ( t = 0 ) ) - ( {V}_{2} ( t = N * {T}_{i n} ) - {V}_{2} ( = 0 ) )}{{V}_{ref , a} - {V}_{2} ( t = 0 )} .$$

After solving the brackets in the first term of the numerator and in the second term of the numerator, this results in:

$${( 1 - η )}^{N} = \frac{{V}_{ref , a} - {V}_{2} ( t = 0 ) - {V}_{2} ( t = N * {T}_{i n} ) + {V}_{2} ( t = 0 )}{{V}_{ref , a} - {V}_{2} ( t = 0 )} ,$$

and this allows the numerator to be simplified as follows:

$${( 1 - η )}^{N} = \frac{{V}_{ref , a} - {V}_{2} ( t = N * {T}_{i n} )}{{V}_{ref , a} - {V}_{2} ( t = 0 )} .$$

Solving the fraction results in:
V_{ref,a}−V₂(t=N*Tᵢₙ)=(V_{ref,a}−V₂(t=0))*(1−η)^{N}
−V₂(t=N*Tᵢₙ)=[(V_{ref,a}−V₂(t=0))*(1−η)^{N}]−V_{ref,a}
V₂(t=N*Tᵢₙ)=V_{ref,a}−[(V_{ref,a}−V₂(t=0))*(1−η)^{N}]
V₂(t=N*Tᵢₙ)=V_{ref,a}+[−(V_{ref,a}−V₂(t=0))*(1−η)^{N}]
V₂(t=N*Tᵢₙ)=V_{ref,a}+[(−V_{ref,a}+V₂(t=0))*(1−η)^{N}]

After conversion of the terms V_{ref,a} and V₂(t=0) in the first bracket on the right-hand side the equation for the recursive calculation of the second voltage V₂(t=N*Tᵢₙ) on the basis of equation (8) becomes:
V₂(t=N*Tᵢₙ)=V_{ref,a}+[(V₂(t=0)-−V_{ref,a})*(1−η)^{N}]

The circuit arrangement 300 described with reference to FIG. 3 will be used in the following text as an outline circuit diagram for the embodiments of the invention which will be described in the following text.

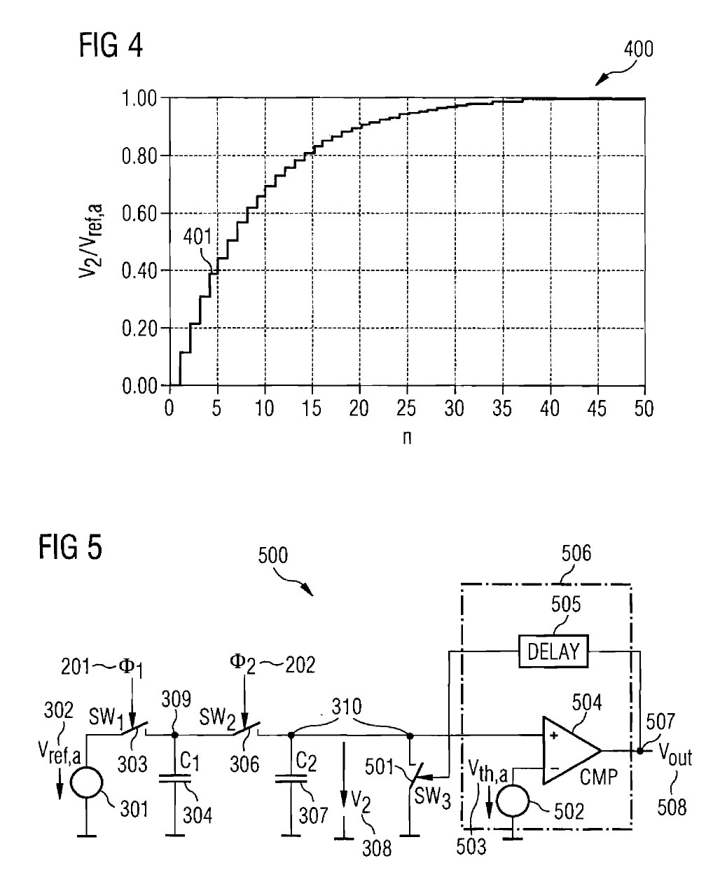

With reference to FIG. 4, a diagram 400 of the waveform of the second voltage V₂ 308 (described for the form of the circuit arrangement as described in FIG. 3) will be explained in the following text.

The diagram 400 illustrates the typical voltage waveform 401 for the circuit arrangement 300 illustrated in FIG. 3, in which the second voltage V₂ 308, which has been normalized with respect to the first reference voltage V_{ref,a} 302, is illustrated as a function of the number of periods or cycles, and in which η= 1/9 and C₂=8*C₁, in accordance with equation (2). Furthermore, because of the switching cycles, the voltage waveform 401 is stepped, with the size of the respective step decreasing with each cycle or each period. In other words, the circuit arrangement 300 makes it possible for the second voltage V₂ 308 to tend asymptotically to the first reference voltage 302 as the number of periods or cycles increases. Low-impedance switch units are used for the switch units 303, 306 on the basis of the embodiments of the invention. Furthermore, capacitances with low supply-line resistances, that is to say capacitances which can be charged and discharged in a short time period, are used, thus reducing the time duration for one cycle or one period, and in consequence the time duration for reaching the desired second voltage V₂ 308.

It is necessary for a frequency-divider circuit to be non-monotonic in the voltage waveform of the second voltage V₂ 308, so that the overall process is periodic.

A frequency-divider circuit arrangement 500 according to one embodiment of the invention will be described in the following text with reference to FIG. 5.

The frequency-divider circuit arrangement 500 includes the same components as the outline circuit diagram 300 illustrated in FIG. 3, a capacitance discharge device 501 and a capacitance discharge device control unit 506 with a first threshold-value voltage source 502, which produces a first threshold-value voltage V_{th,a} 503, a first comparator unit 504 for comparison of the electrical voltage across the second capacitance C₂ 307 with the predetermined first threshold-value voltage V_{th,a} 503, and for production of a comparison-result signal Vₒᵤₜ 508 at its output, and a delay element 505, which is connected between the output 507 of the first comparator unit 504 and the capacitance discharge device 501, in order to delay the comparison-result signal Vₒᵤₜ 508.

Furthermore, the first comparator unit 504 may be a comparator, the delay element 505 may be a latch, and the capacitance discharge device 501 may be a third switch unit or a switch.

The first comparator unit 504 is coupled by a first connection to the threshold-value voltage source 502, and by a second connection to the second capacitance C₂ 307.

The capacitance discharge device 501 is coupled by one connection to the second node 310, and to the first connection of the comparator unit 504, and by a second connection to the ground potential GND. The delay element 505 is electrically coupled by a first connection to the output 507 of the comparator unit 504, and by a second connection to the control connection of the capacitance discharge device 501, with the delay element 505 receiving a signal from the first comparator unit 504, and delaying it for a predetermined time period.

According to an embodiment of the invention, the signals which have been delayed by the delay element 505 control the capacitance discharge device 501, with the second voltage V₂ 308 across the second capacitance C₂ 307 being compared in this case, by means of the comparator unit 504, with the first threshold-value voltage V_{th,a} 503 from the first threshold-value voltage source 502. If the value of the second voltage V₂ 308 across the second capacitance C₂ 307 exceeds the value of the first threshold-value voltage V_{th,a} 503, a different signal is produced at the output 507 of the first comparator unit 504. This signal is used to control and activate the capacitance discharge device 501 by means of the delay element 505, so that the second capacitance C₂ 307 is discharged.

The delay element 505 is provided in order to guarantee a sufficiently long time duration for the drive signal for the capacitance discharge device 501, since the signal at the output 507 of the first comparator unit 504 changes back again to the previous state as soon as the value of the first threshold-value voltage V_{th,a} 503 is undershot at the second connection of the comparator unit 504. There is no need to define the time constant of the delay element 505 exactly, but this time constant should be sufficiently long that the second capacitance C₂ 307 has discharged completely, and shall be shorter than the duration Tᵢₙ, so that the stepped charging process is carried out correctly again after a discharging process.

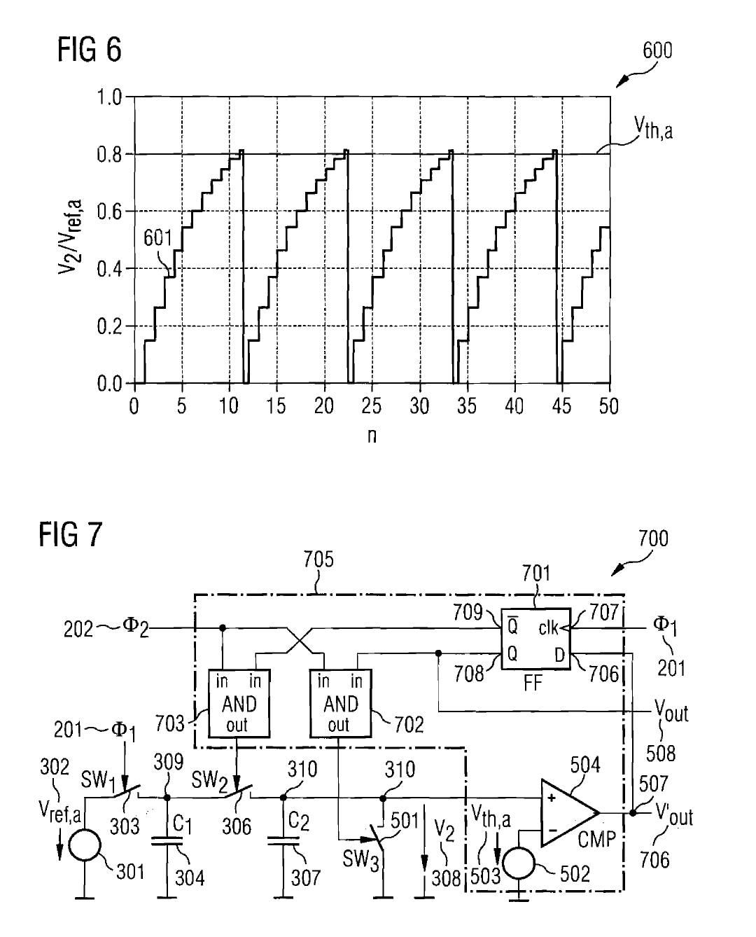

With reference to FIG. 6, the following text describes a diagram 600 of a voltage waveform 601 in the frequency-divider circuit arrangement 500 according to the first embodiment of the invention.

The diagram 600 illustrates a voltage waveform 601 for the second voltage V₂ 308 (which has been normalized with respect to the first reference voltage 302) of the second capacitance C₂ 307 at the second connection of the first comparator unit 504 for an example in which V_{th,a}=0.8*V_{ref,a} and η=½, with the binary comparison-result signal 508 being tapped off at the output of the first comparator unit 504, and with this signal being at the frequency
fₒᵤₜ=(N*Tᵢₙ)⁻¹ (11)

where the definition in the equation (10) also applies to N.

A frequency-divider circuit arrangement 700 according to the second embodiment of the invention will be described in the following text with reference to FIG. 7.

The frequency-divider circuit arrangement 700 includes the same components as the outline circuit diagram 300, the capacitance discharge device 501 and a capacitance discharge device control unit 707 with the first threshold-value voltage source 502, the first comparator unit 504, a state memory 701, a first logic element 702, a second logic element 703 and a signal V′ₒᵤₜ 704, which is produced at the output 507 of the first comparator unit 504, with the state memory 701 being a D-flipflop, which includes a data input 706, a clock input 707, a first output 708 and a second output 709. The data input 706 is coupled to the output 507 of the first comparator unit 504, and the first clock signal Φ₁ 201 is applied to the clock input 707, thus clocking the D-flipflop 701. The first logic element 702 and the second logic element 703 are in the form of AND gates, which each comprise a first input, a second input and one output, with the first input of the first logic element 702 being electrically coupled to the first output 708 of the first state memory 701, with the second clock signal Φ₂ 202 being applied to the second input of the first logic element 702, and with the output of the first logic element 702 being electrically coupled to a control connection of the capacitance discharge device 501, so that the capacitance discharge device 501 is switched as a function of the output signal from the first logic element 702. The first input of the second logic element 703 is electrically coupled to the second output 709 of the first state memory 701, with the second clock signal Φ₂ 202 being applied to the second input of the second logic element 703 and with the output of the second logic element 703 being electrically coupled to a control connection of the second switch unit 306, so that the second switch unit 306 is switched as a function of the output signal from the second logic element 703.

In contrast to the frequency-divider circuit arrangement 500, on the basis of the frequency-divider circuit arrangement 700, the output signal V′ₒᵤₜ 706 from the first comparator unit 504 is transferred to the clocked D-flipflop 701 on activation of the first clock signal Φ₁ 201, that is to say when the first clock signal Φ₁ 201 changes from a low state to a high state, so that, on activation of the second logic element 703 by means of the second clock signal Φ₂ 202, either the second switch unit 306 is closed (thus initiating further charging of the second capacitance C₂ 307) or, on activation of the first logic element 702 by means of the second clock signal Φ₂ 202, the capacitance discharge device 501 is activated, thus discharging the second capacitance C₂ 307. This synchronization of the discharge process with the first clock signal Φ₁ 201 and with the second clock signal Φ₂ 202 results in an output frequency, which is not the same as the output frequency fₒᵤₜ in the equation (11), of:
fₒᵤₜ=[(N+1)*Tᵢₙ]⁻¹ (12)

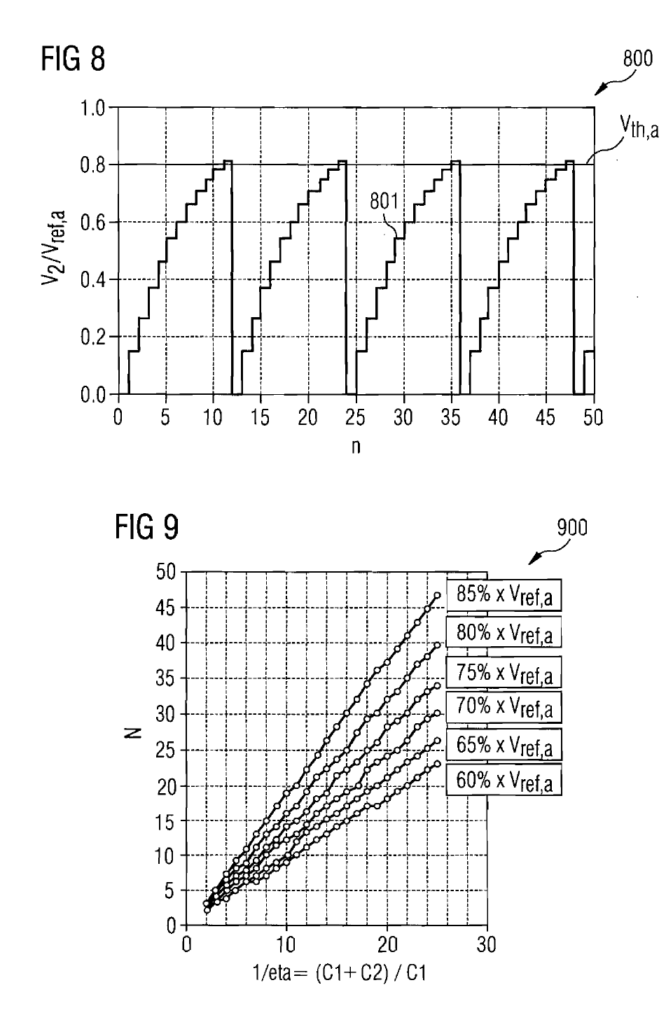

A diagram 800 of a voltage waveform 801 in the frequency-divider circuit arrangement 700 according to the second embodiment of the invention will be described in the following text with reference to FIG. 8.

The diagram 800 illustrates a voltage waveform 801 for the second voltage V₂ 308 (which has been normalized with respect to the first reference voltage V_{ref,a} 302) across the second capacitance C₂ 307 at the second connection of the first comparator unit 504 for an example in which V_{th,a}=0.8*V_{ref,a} and η= 1/7, with the binary comparison-result signal 508 being tapped off at the output 507 of the first comparator unit 504 and being at a frequency in accordance with equation (11), with the definition in equation (10) once again applying to N. As illustrated in the diagram 800, the second capacitance C₂ 307 is discharged only when the second voltage V₂ 308 across the second capacitance C₂ 307 exceeds the value of the first threshold-value voltage V_{th,a} 503.

A diagram 900 for the value of the parameter N based on equation (10) for those embodiments of the frequency-divider circuit arrangements according to the invention which have been discussed so far will be described in the following text with reference to FIG. 9.

The diagram 900 illustrates the values of the parameter N as a function of 1/η for various threshold values of the first threshold-value voltage V_{th,a} 503, which are quoted as fractions of the first reference voltage V_{ref,a} 302.

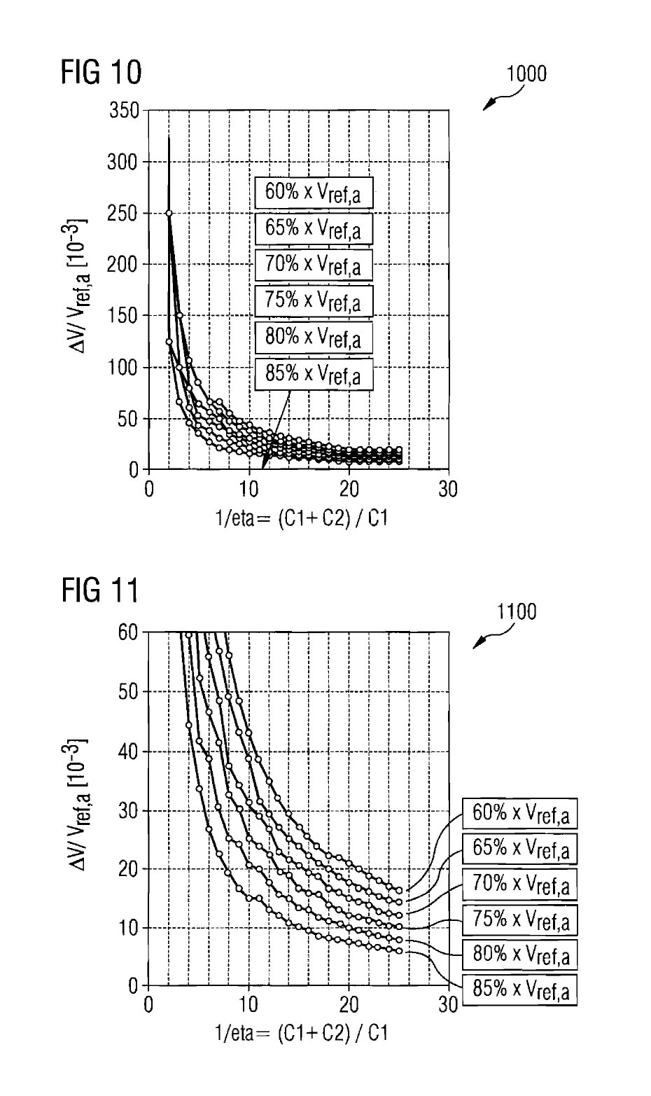

A diagram 1000 of the magnitude of the final voltage step across the second capacitance C₂ 307 will be described in the following text with reference to FIG. 10.

The diagram 1000 illustrates the magnitude of the last voltage step across the second capacitance C₂ 307 before the discharge process, with this having been normalized with respect to the first reference voltage 302 and being illustrated as a function of 1/η for various threshold values V_{th,a}, which are indicated as fractions of the first reference voltage 302.

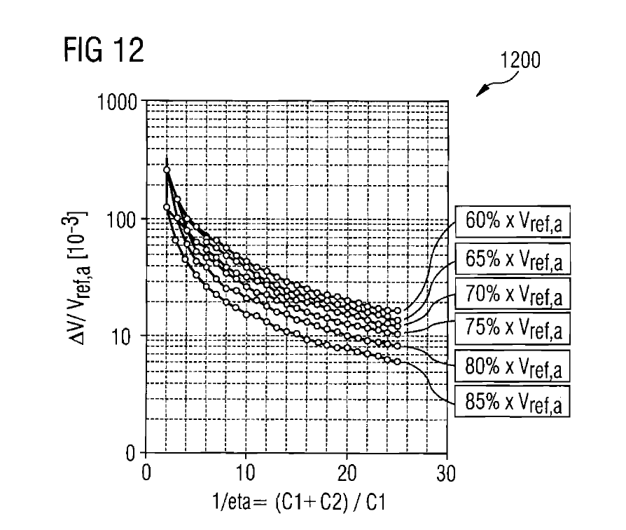

FIG. 11 illustrates a diagram 1100 of an enlarged detail from the diagram 1000, and FIG. 12 illustrates a diagram 1200 of the same data from the diagram 1100, presented in a logarithmic form.

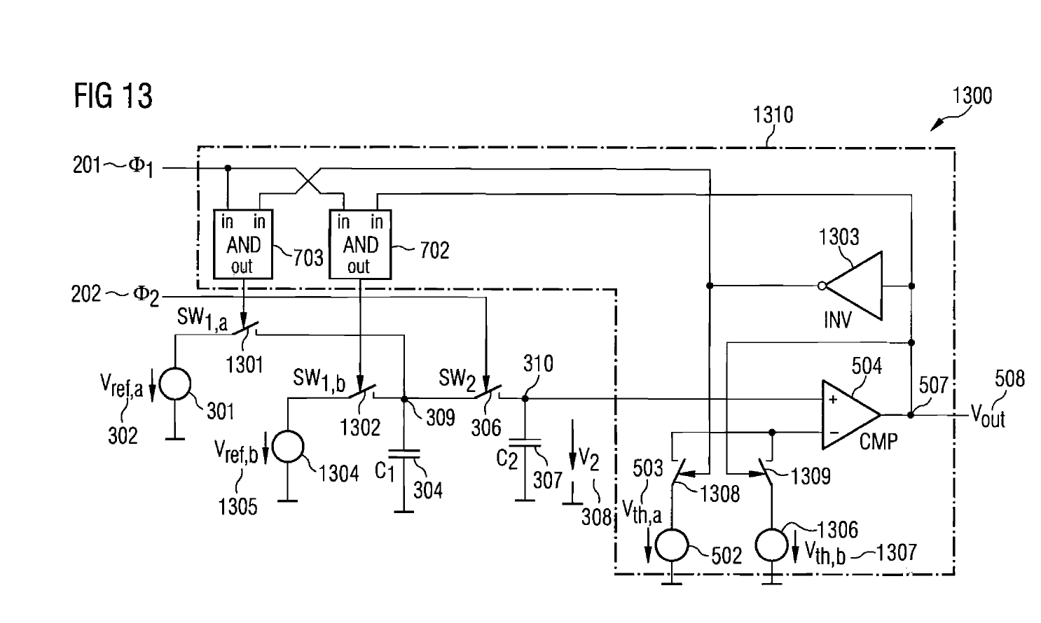

A frequency-divider circuit arrangement 1300 according to the third embodiment of the invention will be described in the following text with reference to FIG. 13.

The frequency-divider circuit arrangement 1300 includes the same components as the outline circuit diagram 300, a capacitance discharge device control unit 1310 with the first logic element 702, the second logic element 703, the first switch unit 303 with a first switch unit element 1301 and a second switch unit element 1302, an inverter circuit 1303, a second reference voltage source 1304 which produces a second reference voltage V_{ref,b} 1305, a second threshold-value voltage source 1306 which produces a second threshold-value voltage V_{th,b} 1307, a fourth switch unit 1308 and a fifth switch unit 1309, with the first reference voltage V_{ref,a} 1305 being applied to a first connection 1311 of the first switch unit element 1301, and with a second connection 1312 of the first switch unit element 1301 being coupled to the first capacitance C₁ 304.

The second reference voltage V_{ref,b} 1305 is applied to a first connection 1313 of the second switch unit element 1302, and a second connection 1314 of the second switch unit element 1302 is coupled to the first capacitance C₁ 304.

The first logic element 702 and the second logic element 703 are in the form of AND gates, each of which comprise a first input, a second input and one output.

The first input of the first logic element 702 is electrically coupled to the output 507 of the first comparator unit 504, the first clock signal Φ₁ 201 is applied to the second input of the first logic element 702, and the output of the first logic element 702 is electrically coupled to the control connection of the second switch unit element 1302, so that the second switch unit element 1302 is switched as a function of the output signal from the first logic element 702.

The first input of the second logic element 703 is electrically coupled to the output of the inverter circuit 1303, the first clock signal Φ₁ 201 is applied to the second input of the second logic element 703, and the output of the second logic element 703 is electrically coupled to the control connection of the first switch unit element 1301, such that the first switch unit element 1301 is switched as a function of the output signal from the second logic element 703.

The first threshold-value voltage V_{th,a} 503 is applied to the first connection of the fourth switch unit 1308, its second connection is coupled to the first input of the first comparator unit 504, and its control connection is coupled to the output of the inverter circuit 1303.

The second threshold-value voltage V_{th,b} 1307 is applied to the first connection of the fifth switch unit 1309, its second connection is coupled to the first input of the first comparator unit 504, and its control connection is coupled to the output of the first comparator unit 504, with the second input of the first comparator unit 504 being coupled to the second capacitance C₂ 307.

The embodiments of the invention which have been described so far indicate examples in which the voltage rise in the second voltage V₂ 308 across the second capacitance C₂ 307 take place comparatively slowly and in a stepped manner, while the voltage drop is relatively abrupt, and within one step. An alternative embodiment of the invention provides for the voltage drop of the second voltage V₂ 308 across the second capacitance C₂ 307 to take place comparatively slowly and in a stepped manner, while the voltage rise is relatively abrupt and takes place within one step.

In contrast to the embodiments of the invention which have been discussed so far, the third embodiment indicates a circuitry solution in which both the voltage rise and the voltage drop are stepped.

According to the third embodiment, a lower, second threshold-value voltage V_{th,b} 1307 is also provided, in addition to an upper, first threshold-value voltage V_{th,a} 503.

Furthermore, in addition to the first reference voltage source 301, which in each case results in the charging of the first capacitance C₁ 304 during the charging process of the second capacitance C₂ 307 before the connection of the first capacitance C₁ 304 and of the second capacitance C₂ 307, and which charges the first capacitance C₁ 304 to a defined value so that a specific voltage is produced across the first capacitance C₁ 304, a second reference voltage source 1304 is provided, which in each case results in the first capacitance C₁ 304 being charged during the discharge process of the second capacitance C₂ 307 before the connection of the first capacitance C₁ 304 and of the second capacitance C₂ 307, and the charging of the first capacitance C₁ 304 to a defined value, such that a specific voltage is produced across the first capacitance C₁ 304.

The second switch unit element 1302 is obviously open during a process in which the second capacitance C₂ 307 is being charged while, in contrast, the first switch unit element 1301 is open during a process in which the second capacitance C₂ 307 is being discharged.

In other words, the first capacitance C₁ 304 is charged again while the second capacitance C₂ 307 is being charged, by means of the first reference voltage V_{ref,a} 302, which is produced by the first reference voltage source 301.

During a process in which the second capacitance C₂ 307 is being discharged, the first capacitance C₁ 304 is charged repeatedly by means of the second reference voltage V_{ref,b} 1305, which is produced by the second reference voltage source 1304.

In other words, the first capacitance C₁ 304 is repeatedly charged, during a process in which the second capacitance C₂ 307 is being charged or discharged, independently of the second capacitance C₂ 307, either by means of the first reference voltage V_{ref,a} 302, which is produced by the first reference voltage source 301, or by means of the second reference voltage V_{ref,b} 1305, which is produced by the second reference voltage source 1304.

On the basis of these conventions relating to the charging and discharging processes, then V_{ref,a}>V_{ref,b}. Furthermore, the first switch unit element 1301 and the second switch unit element 1302 are provided instead of a single switch unit 303 and, during the charging or discharging process, couple the first capacitance C₁ 304 either to the first reference voltage source 301 or to the second reference voltage source 1304, in synchronism with the first clock signal Φ₁ 201.

According to the third embodiment of the invention, the choice as to which of the two threshold-value voltages V_{th,a} 503, V_{th,b} 1307 is applied to the first connection of the first comparator unit 504 and of which reference voltage source 301, 1304 is activated in synchronism with the first clock signal Φ₁ 201, is made by means of a logic operation on the output signal from the first comparator unit 504 with the first clock signal Φ₁ 201 by means of the first logic element 702, and by means of a logic operation on the output signal 507 (which has been inverted by the inverter circuit 1303) from the first comparator unit 504 with the first clock signal Φ₁ 201, by means of the second logic element 703, in such a manner that

1. as soon as the second voltage V₂ 308 across the second capacitance C₂ 307 is greater than the first threshold-value voltage V_{th,a} 503, the first threshold-value voltage V_{th,a} 503 is decoupled from the first connection of the first comparator unit 504 by means of the fourth switch unit 1308, and the second threshold-value voltage V_{th,b} 1307 is applied to the first connection of the first comparator unit 504, the first switch unit element 1301 is opened independently of the first clock signal Φ₁ 201 and the second switch unit element 1302 is closed in synchronism with the first clock signal Φ₁ 201, so that the second voltage V₂ 308 is reduced in steps and in synchronism with the second clock signal Φ₂ 202, and

2. as soon as the second voltage V₂ 308 across the second capacitance C₂ 307 is less than the second threshold-value voltage V_{th,b} 1307, the second threshold-value voltage V_{th,b} 1307 is decoupled from the first connection of the first comparator unit 504 by means of the fifth switch unit 1309, and the first threshold-value voltage V_{th,a} 503 is applied to the first connection of the first comparator unit 504, the second switch unit element 1302 is opened independently of the first clock signal Φ₁ 201, and the first switch unit element 1301 is closed in synchronism with the first clock signal Φ₁ 201, so that the second voltage V₂ 308 rises in steps and in synchronism with the second clock signal Φ₂ 202.

One advantage of the frequency-divider circuit arrangement 1300 according to the third embodiment of the invention over the frequency-divider circuit arrangements described so far according to the first embodiment and according to the second embodiment is, inter alia, that:
The requirements for the switch units are relaxed. The requirements for the third switch unit according to the first embodiment and according to the second embodiment of the invention are very stringent, since they have to transport a comparatively large amount of charge (=C₂*V_{2,end}) in a short time period at a very high frequency of the input signal. There is no such requirement on the circuit arrangement according to the third embodiment of the invention, since the voltage is increased and reduced in considerably smaller steps, so that the amount of charge to be transported is C₂*{V₂(t=(n+1)*Tᵢₙ)−V₂(t=n*Tᵢₙ)}.
The power balance of the power loss caused by the processes of charging and discharging the second capacitance C₂ 307 is better since, in a corresponding manner to the relatively small voltage steps across the second capacitance C₂ 307, the second capacitance C₂ 307 is in each case charged and discharged with small amounts of charge, and this is not the situation according to the first embodiment and according to the second embodiment of the invention.
The resultant division factor, that is to say the ratio of the frequency of the input signal to the frequency of the output signal with the capacitances of the first capacitance C₁ 304 and of the second capacitance C₂ 307 being the same and with only a small amount of additional circuitry complexity, is in general greater by a factor of approximately 2.

The equations which are required for determination of the desired variables, in particular those for determination of the frequency of the output signal, according to the third embodiment of the invention will be explained in the following text, with these equations indicating the division factor as a function of the parameters V_{ref,a}, V_{ref,b}, V_{th,a}, V_{th,b} and η.

The frequency fₒᵤₜ of the output signal from the frequency-divider circuit arrangement 1300 according to the third embodiment of the invention can be quoted as illustrated in equation (13) below:
fₒᵤₜ=[(Nᵤₚ+N_{down})*Tᵢₙ]⁻¹ (13)

where Nᵤₚ represents the number of periods for the charging process, N_{down} represents the number of periods for the discharge process, Tᵢₙ represents the already mentioned one period of the frequency of the input signal. Nᵤₚ and N_{down} can be calculated as follows:

$$\begin{matrix}{N}_{up} = \{ \begin{matrix}\frac{ln ( 1 - \frac{{V}_{th , a} - {V}_{th , b}}{{V}_{ref , a} - {V}_{th , b}} )}{ln ( 1 - η )} if an integer & Zahl \\ int ( \frac{ln ( 1 - \frac{{V}_{th , a} - {V}_{th , b}}{{V}_{ref , a} - {V}_{th , b}} )}{ln ( 1 - η )} ) + 1 else & sonst\end{matrix} & ( 14 ) \\ {N}_{down} = \{ \begin{matrix}\frac{ln ( 1 - \frac{{V}_{th , b} - {V}_{th , a}}{{V}_{ref , b} - {V}_{th , a}} )}{ln ( 1 - η )} if an integer & Zahl \\ int ( \frac{ln ( 1 - \frac{{V}_{th , b} - {V}_{th , a}}{{V}_{ref , b} - {V}_{th , a}} )}{ln ( 1 - η )} ) + 1 else & sonst\end{matrix} & ( 15 )\end{matrix}$$

If the reference voltages 302, 1304 and the threshold-value voltages 503, 1307 are balanced, that is to say provided that:
|V_{ref,a}−V_{th,a}|=V_{ref,b}−V_{th,b}| (16)
then
Nᵤₚ=N_{down}=N (17)

and equation (13) is simplified to:
fₒᵤₜ=[2 N Tᵢₙ]⁻¹ (18)

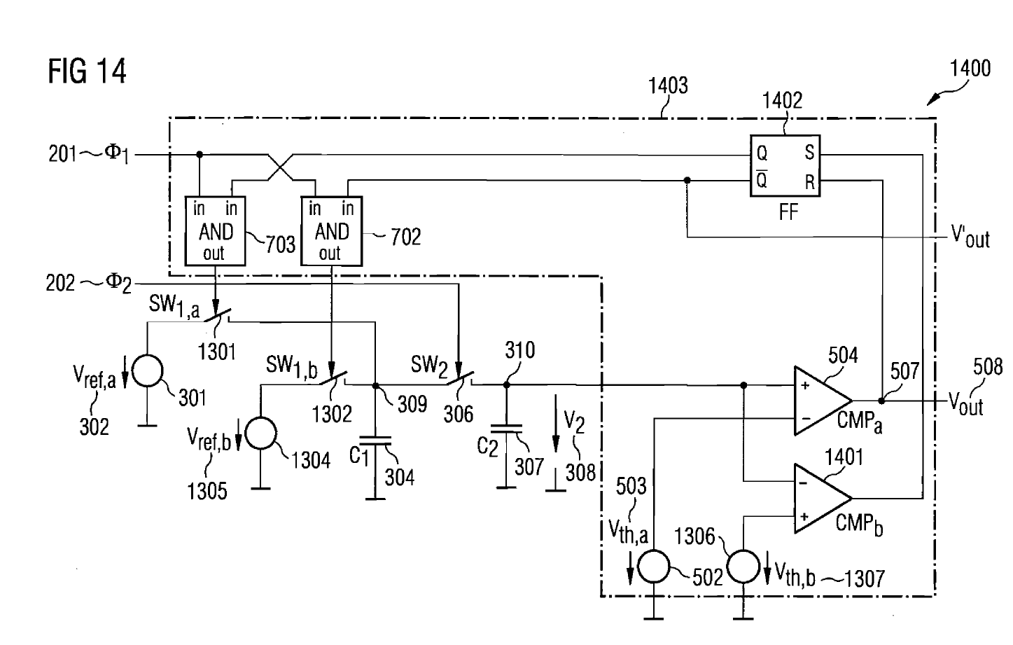

A frequency-divider circuit arrangement 1400 according to the fourth embodiment of the invention will be described in the following text with reference to FIG. 14.

The frequency-divider circuit arrangement 1400 includes the same components as the outline circuit 300, a capacitance discharge device control unit 1403 with the first logic element 702, the second logic element 703, the first switch unit 303 with a first switch unit element 1301 and a second switch unit element 1302, the second reference voltage source 1304, the second threshold-value voltage source 1306, a second comparator unit 1401, a state memory element 1402, in which case the circuitry for the first switch unit element 1301, the second switch unit element 1302, the first logic element 702 and the second logic element 703 as illustrated in FIG. 13 and according to this embodiment is identical.

Furthermore, the first threshold-value voltage V_{th,a} 503 is applied to the first input of the first comparator unit 504, the second input of the first comparator unit 504 is coupled to the second capacitance C₂ 307, and the output of the first comparator unit 504 is coupled to a first input, according to this embodiment to the reset input of the state memory element 1402, which is in the form of an RS-flip-flop.

Furthermore, a first input of the second comparator unit 1401 is coupled to the second capacitance C₂ 307. The second threshold-value voltage V_{th,b} 1307 is applied to the second input of the second comparator unit 1401. The output of the second comparator unit 1401 is coupled to a second input, according to this embodiment to the set input of the state memory element 1402, which is in the form of an RS-flip-flop.

The frequency-divider circuit arrangement 1400 has exactly the same functionality as the frequency-divider circuit arrangement 1300 illustrated in FIG. 13, but in which two comparator units 504, 1401 are used rather than the threshold-value voltage sources 502, 1306 being connected to a first connection of the first comparator unit 504, in which case one input of one comparator unit 504, 1401 is in each case permanently connected to one of the two threshold-value voltage sources 502, 1306, and the signals at the outputs of the comparator units 504, 1401 set and reset the state memory element 1402.

The frequency-divider circuit arrangement 1400 according to the fourth embodiment of the invention offers the advantage over the frequency-divider circuit arrangement 1300 according to the third embodiment, that, at low operating voltages: the drive range, that is to say the range of the voltages which are applied to the connections and inputs of a comparator unit 504, 1401 and at which a frequency-divider circuit arrangement such as this operates correctly can now, for example, be only a few tens of percent of the operating voltage, subject to the constraint of low operating voltages, with this voltage window not being located approximately in the center of the operating voltage range, but normally extending either between the supply potential VDD and VDD/2 or between the ground potential GND and VDD/2. In one embodiment, the comparator units 504 and 1401 in the frequency-divider circuit arrangement 1400 are thus designed in such a manner that the drive range of the first comparator unit 504 covers high input voltages, and the drive range of the second comparator unit 1401 covers low input voltages.

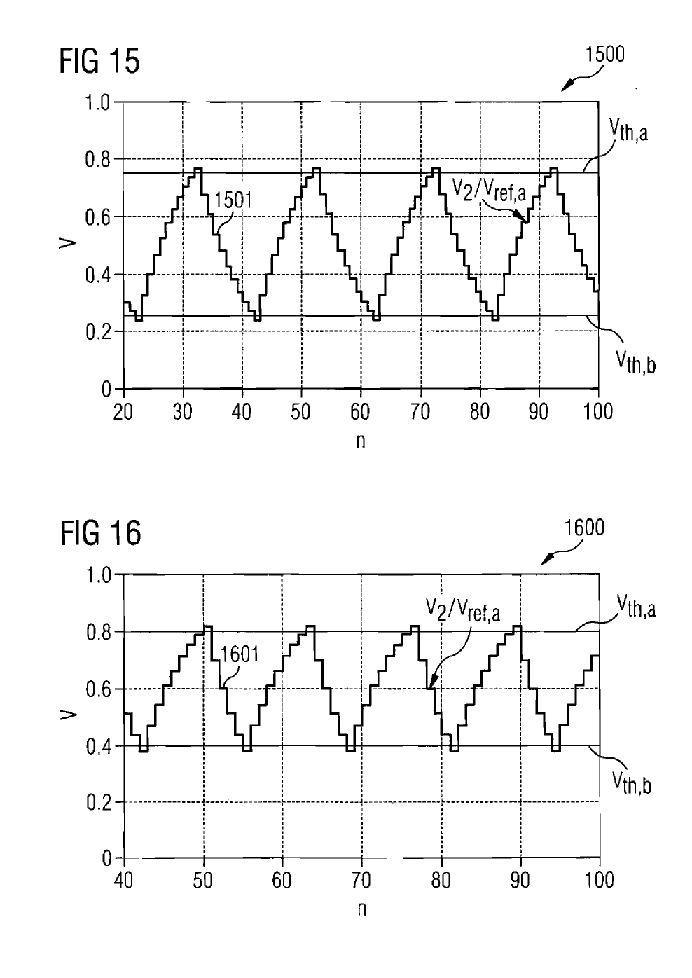

A diagram 1500 of a voltage waveform 1501 of the frequency-divider circuit arrangement 1400 according to the fourth embodiment of the invention will be described in the following text with reference to FIG. 15.

The diagram 1500 illustrates the voltage waveform 1501 of the second voltage V₂ 308, which has been normalized with respect to V_{ref,a} 302, for V_{th,a}=0.75*V_{ref,a}, V_{th,b}=0.25*V_{ref,a} and η= 1/9, in which case, without any restriction to generality, V_{ref,b}=0. The choice of V_{ref,b}=0 therefore does not represent any restriction to generality, since a fixed reference is assigned to only one of four free voltages. Furthermore, on the basis of the condition (equation (16)) explained above, the reference voltages V_{ref,a} 302, V_{ref,b} 1305 and threshold-value voltages V_{th,a} 503, V_{th,b} 1307 are balanced.

A diagram 1600 of a voltage waveform 1601 in the frequency-divider circuit arrangement 1400 according to the fourth embodiment of the invention will be described in the following text with reference to FIG. 16.

The diagram 1600 illustrates the voltage waveform 1601 of the second voltage V₂ 308, which has been normalized with respect to V_{ref,a} 302 for an unbalanced choice of the reference voltages V_{ref,a} 302, V_{ref,b} 1305 and threshold-value voltages V_{th,a} 503, V_{th,b} 1307. Furthermore, V_{th,a}=0.8*V_{ref,a}, V_{th,b}=0.4*V_{ref,a} and η= 1/7, in which case, without any restriction to generality, V_{ref,b}=0. The unbalance in the choice of the reference voltages V_{ref,a} 302, V_{ref,b} 1305 and in the threshold-value voltages V_{th,a} 503, V_{th,b} 1307 with respect to one another is reflected in voltage waveforms of different steepness in the rising and falling branches of the voltage curve or of the voltage waveform 1601 in the diagram 1600.

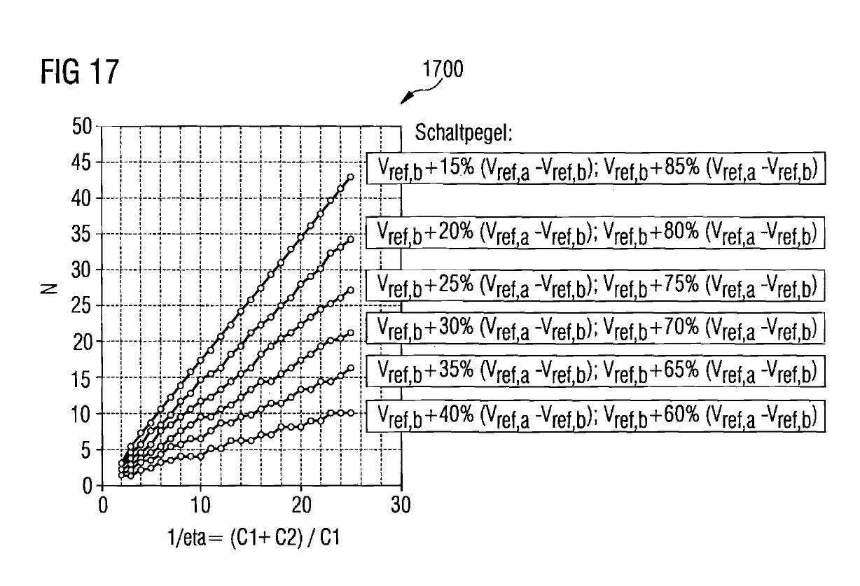

A diagram 1700 for the value of the parameter N based on the equations (14), (15) and (17) for the frequency-divider circuit arrangement 1400 according to the fourth embodiment of the invention will be described in the following text with reference to FIG. 17.

The diagram 1700 illustrates the values of the parameter N as a function of 1/η for various threshold-value voltages V_{th,a} 503 and V_{th,b} 1307, normalized with respect to the reference voltages V_{ref,a} 302 and V_{ref,b} 1305, for a balanced choice of the reference voltages V_{ref,a} 302, V_{ref,b} 1305 and threshold-value voltages V_{th,a} 503, V_{th,b} 1307 with respect to one another, based on equation (16).

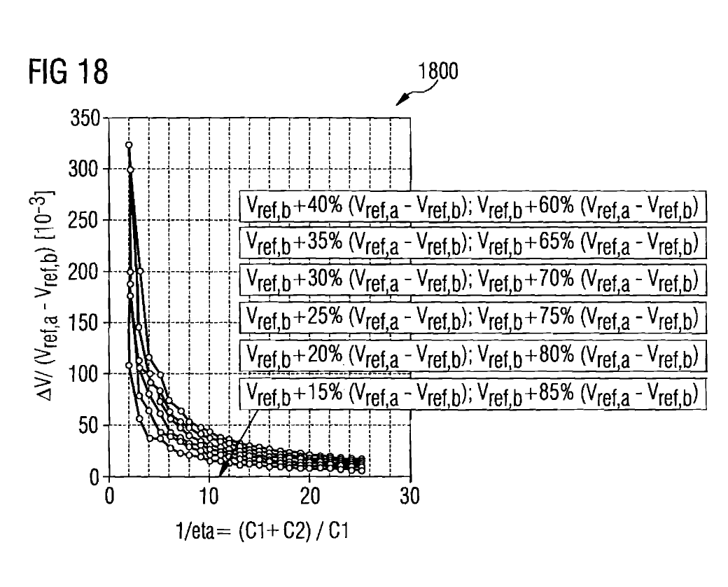

A diagram 1800 for the magnitude of the last voltage step across the second capacitance C₂ 307 will be described in the following text with reference to FIG. 18.

The diagram illustrates the magnitude of the last voltage step across the second capacitance C₂ 307 before a change in the gradient of the second voltage V₂ 308 for a balanced choice of the reference voltages V_{ref,a} 302, V_{ref,b} 1305 and threshold-value voltages V_{th,a} 503, V_{th,b} 1307 with respect to one another, based on equation (16), as a function of 1/η for various threshold-value voltages V_{th,a} 503 and V_{th,b} 1307, normalized with respect to the reference voltages V_{ref,a} 302 and V_{ref,b} 1305.

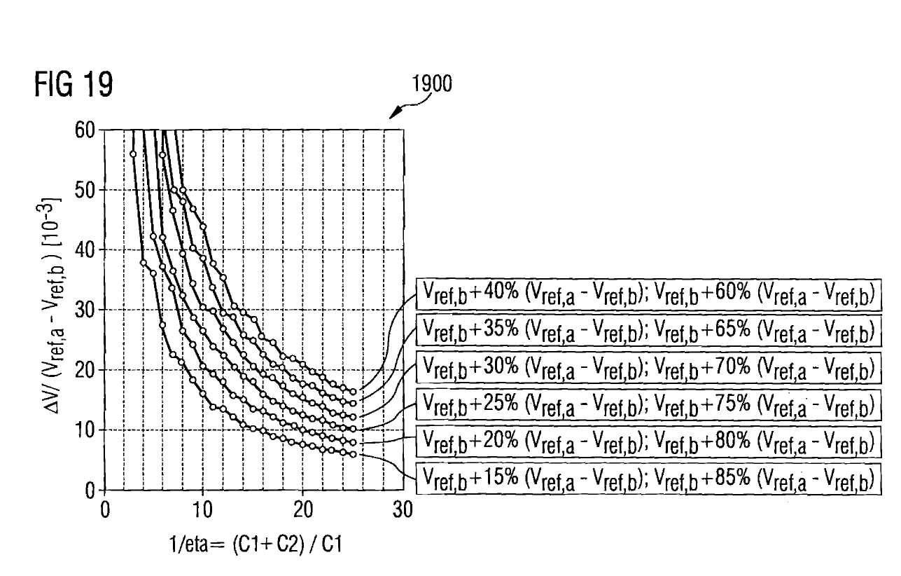

FIG. 19 illustrates a diagram 1900 of an enlarged detail from the diagram 1800.

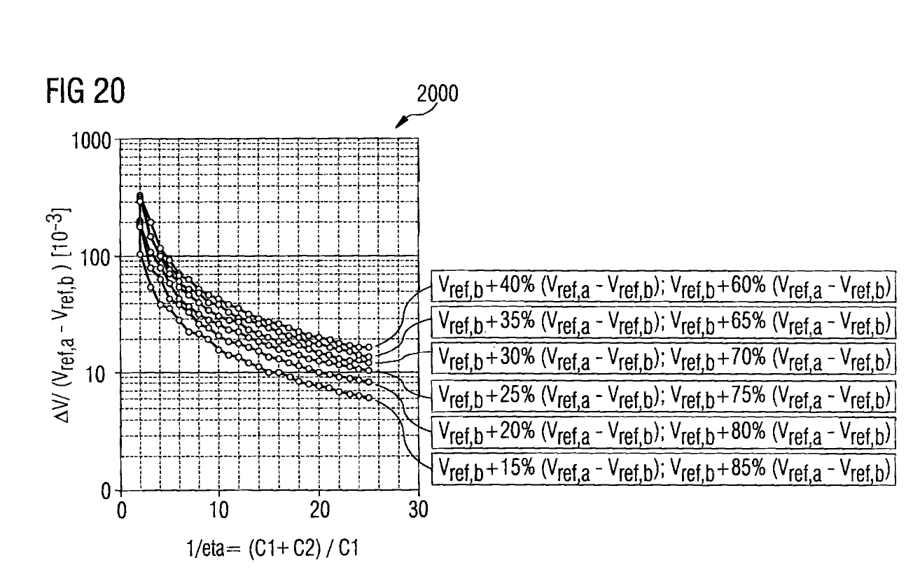

FIG. 20 illustrates a diagram 2000 with the same data as in the diagram 1800, but in a logarithmic form.

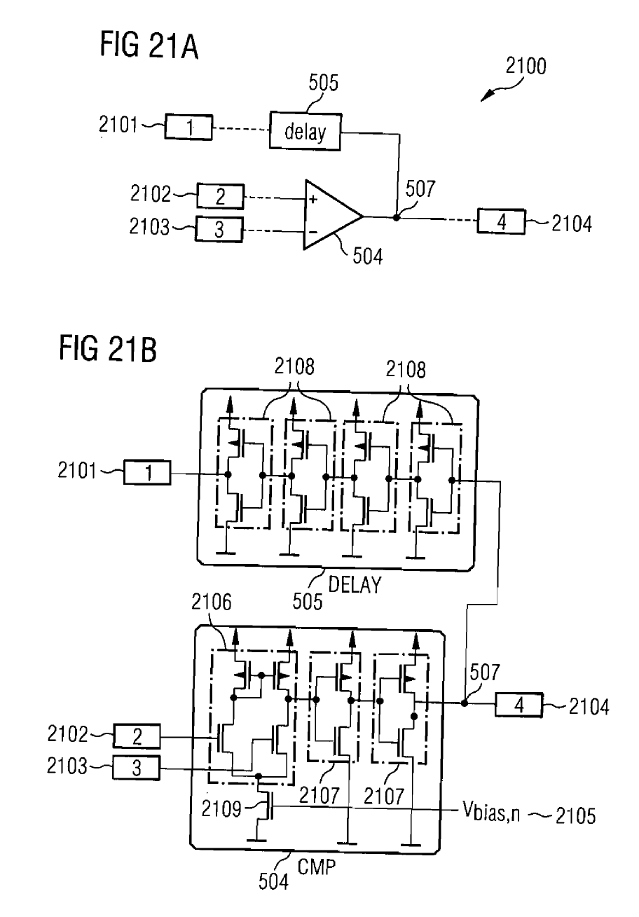

FIG. 21a illustrates a circuit diagram 2100 of a simple circuitry design for a part of the capacitance discharge device control unit 506 according to the first embodiment of the invention.

FIG. 21b illustrates a circuitry implementation of the first comparator unit 504 and of the delay element 505 based on transistors, with a single-ended difference stage 2106 using n-MOS input transistors being buffered at the output by two inverter circuits 2107 being used as the first comparator unit 504. According to the invention, an inverter chain including four inverters 2108 is used for the delay element 505.

A voltage V_{bias,n} 2105 which is used as a bias voltage, is applied to a gate connection of a bias transistor 2109 in the circuitry embodiment of the first comparator unit 504.

According to the first embodiment of the invention, with regard to low-power aspects of the design of the first comparator unit 504, the following should be noted:

provided that, according to the first embodiment of the invention, a potential is applied to the second connection 2102 of the comparator unit 504 which is considerably less than the potential at the first connection 2103, than the entire difference stage 2106 carries no current, in which case, in practice, this potential difference may be about 10-100 mV, depending on the design of the first comparator unit 504 and the technology. In consequence, this circuit part, including the first comparator unit 504 and the delay element 505, contributes to the power loss in the circuit arrangement only if the input voltages are close to one another, and the frequency-divider circuit arrangement is operated close to the switching point. The frequency-divider circuit arrangement reaches operating points such as these periodically at the frequency of the output signal, but not at the frequency of the input signal, since the signal at the output 507 of the first comparator unit 504 changes periodically after the process of discharging the second capacitance C₂ 307. In the same way, the power loss component rises only when the inverters 2107 switch, and this likewise takes place periodically at the frequency of the output signal.

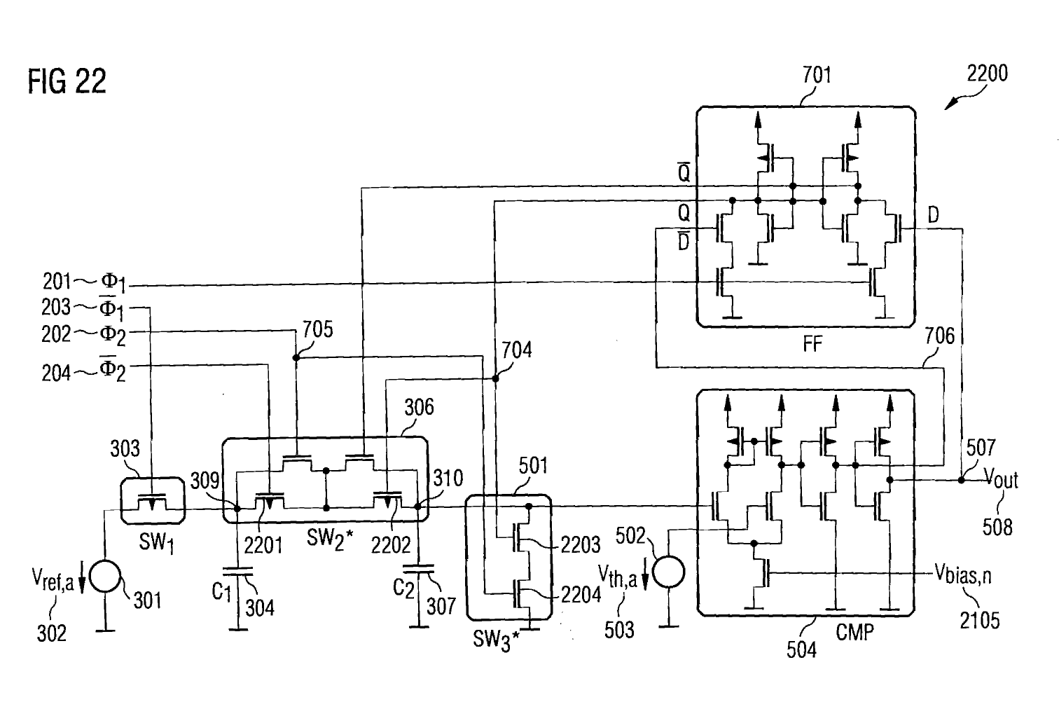

A circuit diagram 2200 of one circuitry implementation of the second embodiment of the invention as illustrated in FIG. 7 will be described in the following text with reference to FIG. 22.

The design of the first comparator unit 504 illustrated in FIG. 22 corresponds to the circuitry implementation of the first comparator unit 504 illustrated in FIG. 21. In addition, the complementary output signal 706 is tapped off at the first comparator unit 504, since the state memory 701 is, in the illustrated form, in principle a clocked RS-flipflop, which is used in this circuitry as a clocked D-flipflop, and must be driven by means of complementary signals, which complementary signals in turn drive disconnected pull-down paths of the n-MOS transistors in time with the first clock signal Φ₁ 201.

The first logic element 702 and the second logic element 703 are not in the form of explicit standard CMOS logic circuits. The logic AND operation on the signals for driving the second switch unit 306 are produced by means of a configuration having two series-connected transfer gates SW₂*2201, 2202 for the second switch unit 306, with the transfer gates 2201, 2202 being driven by means of the second clock signal Φ₂ 202 and by means of the output signals from the state memory 701.

According to the second embodiment of the invention, the AND operation on the signals for driving the capacitance discharge device 501 are produced by means of two series-connected n-MOS switch units (SW₃*), in a similar way to that for the second switch unit 306, with the n-MOS switch units likewise being driven by means of the first clock signal Φ₁ 201 and the output signals from the state memory 701. This version of the capacitance discharge device 501 just with n-MOS transistors and not in the form of transfer gates is sufficient since, in this case, only a ground potential GND is switched, in a pure pull-down path.

The first switch unit 303 is in the form of a p-MOS transistor and not a transfer gate, since the first switch unit 303 switches only potentials which are close to the supply potential VDD, provided that the frequency-divider circuit arrangement is designed sensibly.

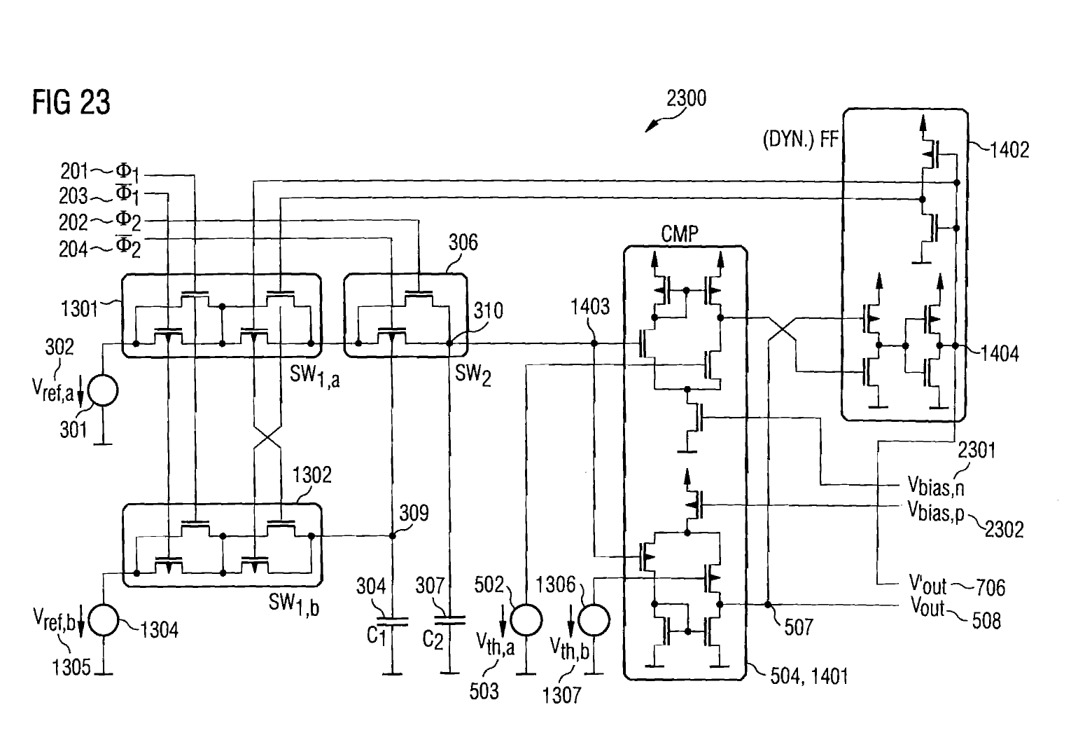

A circuit diagram 2300 of one specific circuitry implementation according to the fourth embodiment of the invention will be explained in the following text with reference to FIG. 23.

The circuit diagram 2300 illustrates a circuitry embodiment of the first switch unit element 1301, and of the second switch unit element 1302, with the first logic element 702 being integrated in the second switch unit element 1302, and the second logic element 703 being integrated in the first switch unit element 1301, of the second switch unit 306, of the first comparator unit 504, of the second comparator unit 1401 and of the state memory element 1402, with the first comparator unit 504 and the second comparator unit 1401 each having a difference stage, and the difference stages being designed on the one hand to be identical to and on the other hand complementary to the already explained circuitry implementations. The state memory element 1402 is replaced and formed by a dynamic circuit arrangement DYN FF, which is set by means of a difference stage, and is reset by means of a complementary difference stage. The AND operations on the clock signals Φ₁ 201, Φ₂ 202, Φ̅₁ 203 and Φ̅₂ 204, and the output signals from the state memory element 1402, and the implementation of the switch units 1301, 1302 and 306 are in the same form as in the second embodiment of the invention, but in which case, according to the fourth embodiment of the invention, transfer gates are used for the switch units 1301, 1302 and 306, since medium signal levels are switched in each case.

Furthermore, a voltage V_{bias,n} 2301 and a voltage V_{bias,p} 2302 are in each case applied as respective bias voltages for the comparator units 504, 1401 to an n-MOS transistor in the difference stage and to a p-MOS transistor in the complementary difference stage in the comparator units 504, 1401.

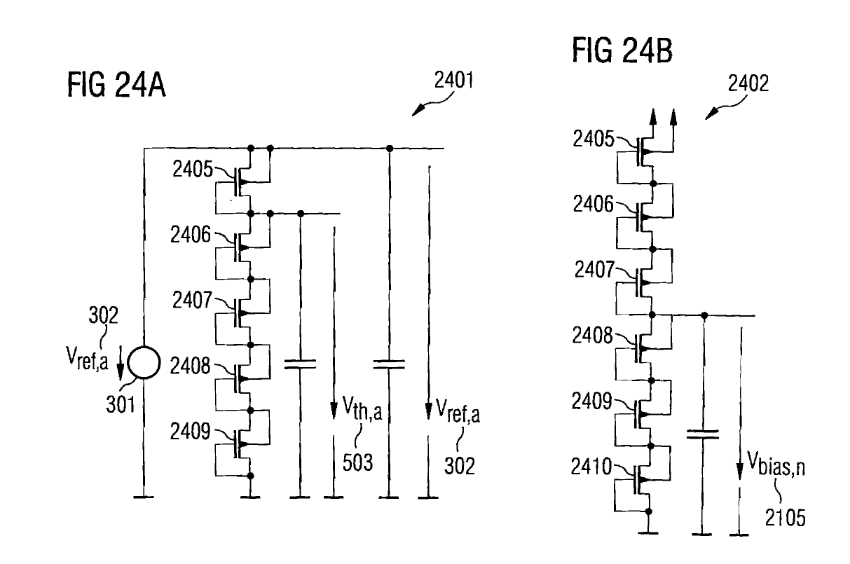

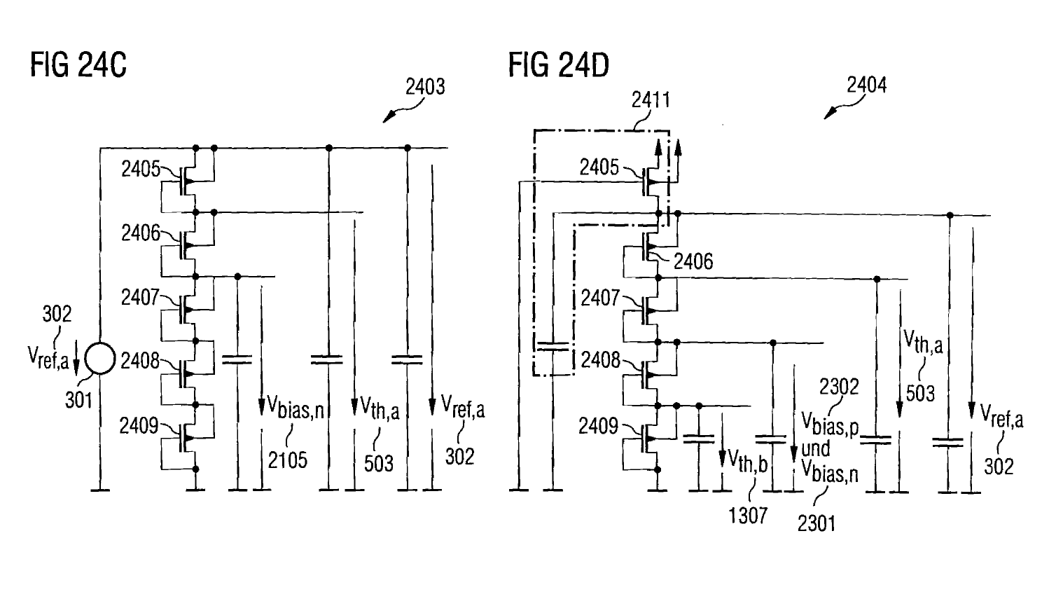

The circuits 2400, 2401, 2402 and 2403 will be described in the following text with reference to FIG. 24, and these can be used with virtually no losses for the generation of the reference voltages V_{ref,a} 302 and V_{ref,b} 1305, of the threshold-value voltages V_{th,a} 503 and V_{th,b} 1307 and of the bias voltages V_{bias,n} 2105, 2301 and V_{bias,p} 2302.

FIG. 24a illustrates a circuit arrangement 2401 for one circuitry implementation for the generation of the first threshold-value voltage V_{th,a} 503 from the given first reference voltage V_{ref,a} 302, in which case the circuit arrangement 2401 can be used in the frequency-divider circuit arrangements illustrated in FIGS. 21 and 22. Furthermore, the circuit arrangement 2401 includes a series circuit formed by the transistors 2405, 2406, 2407, 2408 and 2409, in which case these transistors are p-MOS transistors and are connected in such a way that the gate of the first transistor 2405 in the series circuit is connected to the drain contact of the first transistor 2405 and to the source contact of the following transistor 2406, with the source contact of the following transistor 2406 likewise being electrically coupled to the bulk contact of the following transistor 2406. This type of connection is continued until the last transistor 2409 in the series circuit, with the gate of the last transistor 2409 being coupled to a ground potential GND. The first reference voltage 302 is tapped off with respect to a ground potential GND across the transistor 2405, and is buffered by means of a capacitance. The first threshold-value voltage V_{th,a} 503 is tapped off with respect to a ground potential GND between the transistors 2405 and 2406, and is buffered by means of a capacitance.

If all the transistors 2405 to 2409 that are used in the circuit arrangement 2401 are of identical design, then V_{th,a}=80%*V_{ref,a}. If the operating voltages are around 1 V and the threshold-value voltages are between 300 mV and 400 mV, the operating point of each transistor is in the sub-threshold region, since the voltage drop across each transistor is only 200 mV. In consequence, the value of the parallel current is very small, and contributes only negligibly to the overall power balance. The circuit arrangement 2401 can be operated in the sub-threshold region because the output voltage does not have a resistive load applied to it.

FIG. 24b illustrates a voltage divider chain 2402 from transistors 2405 to 2410, by means of which the bias voltage 2105 for the current-source transistor can be generated in the circuit in the comparator unit in FIGS. 21 and 22. The voltage divider chain 2402 is formed by the p-MOS transistors 2405, 2406, 2407, 2408, 2409 and 2410 connected in series, with the bias voltage V_{bias,n} 2105 being tapped off with respect to a ground potential GND between the transistor 2407 and the transistor 2408.

If the transistors 2405 to 2410 are identical, then V_{bias,n}=0.5*VDD. If the operating voltages are around 1 V and the threshold-value voltages are between 300 mV and 400 mV, the operating point of each transistor is in the sub-threshold region, since the voltage drop across each transistor is only 170 mV. In consequence, the value of the parallel current is very small, and once again contributes only insignificantly to the overall power balance. The circuit arrangement 2402 can be operated in the sub-threshold range because the output voltage does not have a resistive load applied to it. The bias voltage V_{bias,n} 2105 is about 500 mV, so that the current-source transistor which is operated with this voltage in the stages of the comparator unit is operated in inversion. This is intended, in order to operate the circuit of the comparator unit, having the first comparator unit 504 and the second comparator unit 1401, with the required bandwidth.

FIG. 24c illustrates a circuit arrangement 2403 formed from a combination of the circuit arrangements 2401 and 2402, in which case both the required first threshold-value voltage V_{th,a} 503 and the bias voltage V_{bias,n} 2105 for the current-source transistor in the circuit in the comparator unit illustrated in FIGS. 21 and 22 can be produced by means of the circuit arrangement 2403 from the given first reference voltage V_{ref,a} 302. The circuit arrangement 2403 is identical to the circuit arrangement 2401, with the bias voltage V_{bias,n} additionally being tapped off between the transistors 2406 and 2407 in this case.

If the reference voltage is 1 V, then V_{th,a}=800 mV and V_{bias,n}=600 mV.

FIG. 24d illustrates a circuit arrangement 2404 which can be used, for example, for the production of the reference voltages V_{ref,a} 302 and V_{ref,b} 1305 of the threshold-value voltages V_{th,a} 503 and V_{th,b} 1307 and of the bias voltages V_{bias,n} 2105, 2301 and V_{bias,p} 2302 in the frequency-divider circuit arrangement according to the fourth embodiment of the invention, as illustrated in FIG. 23. According to the circuit arrangement 2404, the transistors 2405, 2406, 2407, 2408 and 2409 are connected to one another in series, with the four transistors 2406, 2407, 2408 and 2409 being identical, and being operated in the sub-threshold region when the operating voltage is 1 V and the threshold-value voltages are 300 mV and 400 mV. The first reference voltage V_{ref,a} 302 is tapped off between the transistors 2405 and 2406, the threshold-value voltage V_{th,a} 503 is tapped off between the transistors 2406 and 2407, the bias voltages 2301 and 2302 are tapped off between the transistors 2407 and 2408, and the second threshold-value voltage 1307 is tapped off between the transistors 2408 and 2409.

Because its gate is connected to the ground potential GND in inversion, the transistor 2405 is furthermore operated in the linear region and may have a different geometry to that of the other transistors. The transistor 2405 is operated as a non-reactive resistance and, together with the connected capacitance, produces a low-pass filter 2411 in order to filter and to compensate for voltage fluctuations in the supply voltage VDD, so that the filtered supply potential VDD is used directly as the first reference voltage V_{ref,a} 302. The second reference voltage V_{ref,b} 1305 is in this case chosen to be identical to the ground potential (GND), and the threshold-value voltages V_{th,a} 503 and V_{th,b} 1307 are respectively 750 mV and 250 mV, for an operating voltage of 1 V. The bias voltage for the current-source transistors in the two difference stages in the comparator units 504 and 1401 are chosen to be half the supply potential, VDD/2=500 mV.

According to the voltage diagrams 600 and 800, on the assumption of a realistic value for the first reference voltage V_{ref,a} 302 of 1 V₁ the value of the second voltage 308 can be read directly off the Y-axis in volts for actual circuits using modern CMOS technologies with operating voltages between 1 V and 1.2 V (up to a maximum of 1.5 V), with the first threshold-value voltage being V_{th,a} 0.8 V.

According to the voltage diagrams 1000, 1100 and 1200, on the assumption of a realistic value for the first reference voltage V_{ref,a} 302 of 1 V, the value of the last voltage step of the second voltage 308 before the discharge process can be read directly from the Y axis in mV, for real circuits using modern CMOS technologies and with operating voltages between 1 V and 1.2 V (up to a maximum of 1.5 V).

Furthermore, the supply potential VDD can be used directly as the first reference voltage V_{ref,a} 302, provided that a supply potential VDD is stabilized or that temporary changes in the supply potential VDD occur at a considerably lower frequency than fₒᵤₜ.

The frequency-divider circuit arrangements 500, 700 according to the first and second embodiments, respectively, of the invention, as discussed, represent examples in which the second voltage 308 across the second capacitance C₂ 307 rises comparatively slowly and in a stepped manner, while the drop is relatively abrupt, and occurs within only one step. However, complementary designs to this are also possible, in which the second voltage 308 across the second capacitance C₂ 307 falls comparatively slowly and in a stepped manner, while the rise is relatively abrupt and occurs within only one step.

According to the voltage diagrams 1500 and 1600, on the assumption of a realistic value for the first reference voltage V_{ref,a} 302 of 1 V and subject to the condition V_{ref,b}=0, which is chosen without any restriction to generality, the value of the second voltage 308 can be read directly in volts from the Y-axis for real circuits using modern CMOS technologies and with operating voltages between 1 V and 1.2 V (up to a maximum of 1.5 V), with the first threshold-value voltage V_{th,a} in the voltage diagram 1500 being 0.75 V, and the second threshold-value voltage V_{th,b} being 0.25 V. The first threshold-value voltage V_{th,a} in the voltage diagram 1600 is 0.8, and the second threshold-value voltage V_{th,b} is 0.4 V.

According to the voltage diagrams 1800, 1900 and 2000, on the assumption of a realistic value for the first reference voltage V_{ref,a} 302 of 1 V and subject to the condition V_{ref,b}=0, which is chosen without any restriction to generality, the value of the last voltage step of the second voltage 308 before the change in the gradient of the second voltage 308 can be read directly from the Y-axis in mV for real circuits using modern CMOS technologies, and with operating voltages between 1 V and 1.2 V (up to a maximum of 1.5 V).

Furthermore, the supply potential VDD can be used directly as the first reference voltage V_{ref,a} 302, provided that a supply potential VDD is stabilized or temporary changes in the supply potential VDD occur at a considerably lower frequency than fₒᵤₜ.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A frequency divider circuit arrangement comprising:
a first clock signal;
a second clock signal;
a first switch unit;
a first capacitance connected downstream from the first switch unit;
a second switch unit connected downstream from the first capacitance and controlled by the second clock signal;
a clock signal control unit and a capacitance discharge device control unit; and
a second capacitance connected in parallel to the first capacitance, the clock signal control unit, a capacitance discharge device and the capacitance discharge device control unit.

2. The frequency divider circuit arrangement of claim 1, comprising:
where the clock-signal control unit is onfigured to apply the first clock signal to the first switch unit and to apply the second clock signal to the second switch unit in such a manner that the following processes are carried out repeatedly:
closing the first switch unit such that the first capacitance is electrically charged,
opening the first switch unit,
closing the second switch unit such that charge equalization takes place between the first capacitance and the second capacitance, and
opening the second switch unit.

3. The frequency divider circuit arrangement of claim 2, comprising:
the capacitance discharge device electrically discharging the second capacitance to a predetermined voltage value; and
where the capacitance discharge device control unit is configured to control the capacitance discharge device such that it is activated when the electrical voltage applied to the second capacitance is greater than a predetermined threshold value.

4. The frequency divider circuit arrangement of claim 3, comprising:
wherein the capacitance discharge device control unit comprises a first comparator unit comparing the electrical voltage applied to the second capacitance with the predetermined threshold value, and producing a comparison-result signal at its output

5. A frequency-divider circuit arrangement, comprising:
a first switch unit being controlled by a first clock signal and capable of being coupled to a power supply potential;
a first capacitance being connected downstream from the first switch unit;
a second switch unit being connected downstream from the first capacitance being controlled by a second clock signal;
a second capacitance being connected downstream from the second switch unit and being connected in parallel with the first capacitance;
a clock-signal control unit applying the first clock signal to the first switch unit and applying the second clock signal to the second switch unit in such a manner that the following processes are carried out repeatedly:
closing the first switch unit such that the first capacitance is electrically charged,
opening the first switch unit,
closing the second switch unit such that charge equalization takes place between the first capacitance and the second capacitance,
opening the second switch unit;
a capacitance discharge device electrically discharging the second capacitance to a predetermined electrical voltage value; and
a capacitance discharge device control unit controlling the capacitance discharge device in such a manner that it is activated when the electrical voltage which is applied to the second capacitance is greater than a predetermined threshold value.

6. The frequency-divider circuit arrangement as claimed in claim 5, wherein the second capacitance comprises a capacitance value which is not the same as that of the first capacitance.

7. The frequency-divider circuit arrangement as claimed in claim 6, wherein the value of the second capacitance is greater than the value of the first capacitance.

8. The frequency-divider circuit arrangement as claimed in claim 5, wherein the capacitance discharge device comprises a switch.

9. The frequency-divider circuit arrangement as claimed in claim 5, wherein the capacitance discharge device control unit comprises a first comparator unit comparing the electrical voltage applied to the second capacitance with the predetermined threshold value, and producing a comparison-result signal at its output.

10. The frequency-divider circuit arrangement as claimed in claim 9, wherein the capacitance discharge device control unit comprises a delay element, the delay element being connected between the output of the first comparator unit and the capacitance discharge device, and delaying the comparison result signal.

11. The frequency-divider circuit arrangement as claimed in claim 10, wherein the delay element comprises a latch or an inverter chain.

12. The frequency-divider circuit arrangement as claimed in claim 9, wherein the capacitance discharge device control unit comprises a state memory element, a first logic element and a second logic element.

13. The frequency-divider circuit arrangement as claimed in claim 12, wherein the state memory element being a flipflop, the flipflop comprises a first input, a second input, a first output and a second output, the flipflop being coupled by the first input to the output of the first comparator unit, and being clocked by means of the first clock signal applied to the second input.

14. The frequency-divider circuit arrangement as claimed in claim 12, the first logic element and the second logic element being AND gates, each comprising a first input, a second input and an output;
the first input of the first logic element being electrically coupled to the second output of the first state memory element, the second clock signal being capable of being applied to the second input of the first logic element, and the output of the first logic element being electrically coupled to the third switch unit, such that the capacitance discharge device can be switched as a function of the output signal from the first logic element;
the first input of the second logic element being electrically coupled to the first output of the first state memory element, the second clock signal being capable of being to the second input of the second logic element, and the output of the second logic element being electrically coupled to the second switch unit, such that the second switch unit can be switched as a function of the output signal from the second logic element.

15. The frequency-divider circuit arrangement as claimed in claim 9, wherein the capacitance discharge device control unit comprises an inverter circuit, a first logic element and a second logic element.

16. The frequency-divider circuit arrangement as claimed in claim 15, wherein the first switch unit comprises a first switch unit element and a second switch unit element, a first power supply potential being capable of being applied to a first connection of the first switch unit element, a second connection of the first switch unit element being coupled to the first capacitance, a second power supply potential being capable of being applied to a first connection of the second switch unit element, a second connection of the second switch unit element being coupled to the first capacitance;
the first logic element and the second logic element being AND gates each comprising a first input, a second input and an output;
the first input of the first logic element being electrically coupled to the output of the comparator unit, the first clock signal being capable of being applied to the second input of the first logic element, and the output of the first logic element being electrically coupled to the second switch unit element, such that the second switch unit element can be switched as a function of the output signal from the first logic element;
the first input of the second logic element being electrically coupled to the output of the inverter circuit, the first clock signal being capable of being applied to the second input of the second logic element, and the output of the second logic element being electrically coupled to the first switch unit element, such that the first switch unit element can be switched as a function of the output signal from the second logic element.

17. The frequency-divider circuit arrangement as claimed in claim 16, further comprising:
a fourth switch unit, to whose first connection a first comparison potential can be applied, and whose second connection is coupled to a first input of the comparator unit, whose control connection is coupled to the output of the inverter circuit;
a fifth switch unit, to whose first connection a second comparison potential can be applied, and whose second connection is coupled to the first input of the comparator unit, whose control connection is coupled to the output of the comparator unit;
the second input of the comparator unit being coupled to the second capacitance.

18. The frequency-divider circuit arrangement as claimed in claim 12, wherein the first switch unit comprises a first switch unit element and a second switch unit element, a first power supply potential being capable of being applied to a first connection of the first switch unit element, a second connection of the first switch unit element being coupled to the first capacitance;
a second power supply potential being capable of being applied to a first connection of the second switch unit element, a second connection of the second switch unit element being coupled to the first capacitance;
the first logic element and the second logic element being AND gates each comprising a first input, a second input and an output;
the first input of the first logic element being electrically coupled to the second output of the switching element, the first clock signal being capable of being applied to the second input of the first logic element, and the output of the first logic element being capable of being coupled to the second switch unit element, such that the second switch unit element can be switched as a function of the output signal from the first logic element;
the first input of the second logic element being electrically coupled to the first output of the state memory element, the first clock signal being capable of being applied to the second input of the second logic element, and the output of the second logic element being electrically coupled to the first switch unit element, such that the first switch unit element can be switched as a function of the output signal from the second logic element.

19. The frequency-divider circuit arrangement as claimed in claim 18, wherein a first comparison potential is capable of being applied to a first input of the first comparator unit, a second input of the first comparator unit being coupled to the second capacitance, and the output of the first comparator unit being coupled to a first input of the state memory element;
comprising a second comparator unit, whose first input is coupled to the second capacitance, to whose second input a second comparison potential can be applied, and whose output is coupled to a second input of the state memory element.

20. A method for frequency division, comprising:
controlling a first switch unit which can be coupled to a power supply potential, by means of a first clock signal;
controlling a second switch unit by means of a second clock signal, the second switch unit being connected downstream from a first capacitance and the first capacitance being connected downstream from the first switch unit;
applying the first clock signal to the first switch unit and applying the second clock signal to the second switch unit in such a manner that the following steps are carried out repeatedly:
closing the first switch unit such that the first capacitance is electrically charged,
opening the first switch unit,
closing the second switch unit such that charge equalization takes place between the first capacitance and a second capacitance which is connected downstream from the second switch unit and is connected in parallel with the first capacitance,
opening the second switch unit; and
electrically discharging the second capacitance to a predetermined electrical voltage value when the electrical voltage which is applied to the second capacitance is greater than a predetermined threshold value.

21. The method as claimed in claim 20, further comprising comparing the electrical voltage which is applied to the second capacitance with the predetermined threshold value and producing a comparison-result signal.

22. The method as claimed in claim 21, further comprising delaying the comparison-result signal.

23. A frequency-divider circuit arrangement, comprising:
a first switch unit being controlled by a first clock signal and being capable of being coupled to a power supply potential;
a first capacitance being connected downstream from the first switch unit;
a second switch unit being connected downstream from the first capacitance and being controlled by a second clock signal;
a second capacitance being connected downstream from the second switch unit and being connected in parallel with the first capacitance;
means to control a clock-signal applying the first clock signal to the first switch unit and applying the second clock signal to the second switch unit in such a manner that the second capacitance is charged in a stepped manner in that the following steps are carried out repeatedly:
closing the first switch unit such that the first capacitance is electrically charged,
opening the first switch unit, closing the second switch unit such that charge equalization takes place between the first capacitance and the second capacitance,
opening the second switch unit;
a capacitance discharge device electrically discharging the second capacitance to a predetermined electrical voltage value;
a capacitance discharge device control unit controlling the capacitance discharge device in such a manner that it is activated when the electrical voltage which is applied to the second capacitance is greater than a predetermined threshold value.

24. An RF-ID device comprising:
an RFID tag circuit including a frequency divider circuit arrangement comprising a first clock signal, a second clock signal, a first switch unit, a first capacitance connected downstream from the first switch unit, a second switch unit connected downstream from the first capacitance and controlled by the second clock signal, a clock signal control unit and a capacitance discharge device control unit; and a second capacitance connected in parallel to the first capacitance, the clock signal control unit, a capacitance discharge device and the capacitance discharge device control unit.

25. The device of claim 24, comprising:
where the clock-signal control unit is onfigured to apply the first clock signal to the first switch unit and to apply the second clock signal to the second switch unit in such a manner that the following processes are carried out repeatedly:
closing the first switch unit such that the first capacitance is electrically charged,
opening the first switch unit,
closing the second switch unit such that charge equalization takes place between the first capacitance and the second capacitance, and
opening the second switch unit.

26. The device of claim 25, comprising:
the capacitance discharge device electrically discharging the second capacitance to a predetermined voltage value; and
where the capacitance discharge device control unit is configured to control the capacitance discharge device such that it is activated when the electrical voltage applied to the second capacitance is greater than a predetermined threshold value.
